(19) United States
(12) Patent Application Publication
(10) Pub. No.: US 2024/0096919 A1
(43) Pub. Date: Mar. 21, 2024

(54) SEMICONDUCTOR DEVICE, IMAGING DEVICE, AND MANUFACTURING METHOD

(71) Applicant: SONY SEMICONDUCTOR SOLUTIONS CORPORATION, KANAGAWA (JP)

(72) Inventor: TAKUSHI SHIGETOSHI, KANAGAWA (JP)

(21) Appl. No.: 18/264,790

(22) PCT Filed: Jan. 6, 2022
(86) PCT No.: PCT/JP2022/000169

§ 371 Date: Aug. 9, 2023

(30) Foreign Application Priority Data
Feb. 25, 2021 (JP) 2021-028236

(51) Int. Cl. H01L 27/146

(52) U.S. Cl. CPC H01L 27/14636; H01L 27/14634; H01L 27/1469

(57) ABSTRACT

The present technology relates to a semiconductor device, an imaging device, and a manufacturing method capable of forming a via connected to wirings at different depths so as not to cause a defect.

A plurality of vias is provided, and an aspect ratio defined by a depth and a width of the via is substantially the same in the plurality of vias. The via is connected to the wiring in the wiring layer constituting the chip. The plurality of vias includes a first via that penetrates a chip stacked in the wiring layer and a second via that does not penetrate the chip. The present technology can be applied to, for example, a chip on which a solid-state imaging element is formed and an imaging element in which other chips are stacked.

### TECHNICAL FIELD

The present technology relates to a semiconductor device, an imaging device, and a manufacturing method, and relates to, for example, a semiconductor device, an imaging device, and a manufacturing method in which a plurality of chips having different sizes is stacked and wiring connected to the outside is provided.

### BACKGROUND ART

Conventionally, high performance of a semiconductor element has been realized by highly integrating transistors and wirings due to miniaturization of a manufacturing process. However, as miniaturization progresses, a decrease in the pace of performance improvement due to side effects of parasitic elements and the like, and an increase in development and manufacturing cost have become problems.

Therefore, in recent years, chips having different functions are manufactured by an optimal process and three-dimensionally stacked, thereby developing integration and high performance of semiconductor elements. For example, Patent Document 1 proposes a method in which wirings of chips are stacked to face each other, and electrical connection with the outside is performed using vias penetrating the chips.

### CITATION LIST

### Patent Document

Patent Document 1: U.S. Pat. No. 9,806,055

### SUMMARY OF THE INVENTION

### Problems to be Solved by the Invention

In a case where vias having different depths are formed, there is a possibility that all vias cannot be formed with equivalent accuracy in a process such as etching or metal filling, and defective vias are formed. In a case where vias having different depths are formed, it is desired to reduce the incidence of defective vias.

The present technology has been made in view of such a situation, and enables vias having different depths to be accurately formed.

### Solutions to Problems

A semiconductor device according to one aspect of the present technology is a semiconductor device including a plurality of vias, in which an aspect ratio defined by a depth and a width of a via is substantially same in the plurality of vias.

An imaging device according to one aspect of the present technology is an imaging apparatus including: a first chip on which a solid-state imaging element is formed; a second chip that processes a signal from the first chip; and a plurality of vias formed in the first chip and the second chip, in which an aspect ratio defined by a depth and a width of a via is substantially same in the plurality of vias.

A manufacturing method according to one aspect of the present technology is a manufacturing method for manufacturing a semiconductor device including a plurality of vias, the manufacturing method including forming a hole in which a width of a via is set such that an aspect ratio defined by a depth and a width of the via is substantially same in the plurality of vias.

A semiconductor device according to one aspect of the present technology includes a plurality of vias, in which an aspect ratio defined by a depth and a width of a via is substantially same in the plurality of vias.

An imaging device according to one aspect of the present technology includes: a first chip on which a solid-state imaging element is formed; a second chip that processes a signal from the first chip; and a plurality of vias formed in the first chip and the second chip, in which an aspect ratio defined by a depth and a width of a via is substantially same in the plurality of vias.

A manufacturing method for manufacturing a semiconductor device including a plurality of vias according to one aspect of the present technology includes forming a hole in which a width of a via is set such that an aspect ratio defined by a depth and a width of the via is substantially same in the plurality of vias.

Note that the imaging device may be an independent device, or an internal block constituting one device.

### BRIEF DESCRIPTION OF DRAWINGS

FIG. 1 is a diagram illustrating a configuration of an embodiment of a semiconductor device to which the present technology is applied.

FIG. 2 is a diagram for explaining a configuration of a semiconductor device in a second embodiment.

FIG. 3 is a diagram for explaining a configuration of a semiconductor device in a third embodiment.

FIG. 4 is a diagram for explaining manufacturing of the semiconductor device in the third embodiment.

FIG. 5 is a diagram for explaining manufacturing of the semiconductor device in the third embodiment.

FIG. 6 is a diagram for explaining a configuration of a semiconductor device in a fourth embodiment.

FIG. 7 is a diagram for explaining manufacturing of the semiconductor device in the fourth embodiment.

FIG. 8 is a diagram for explaining manufacturing of the semiconductor device in the fourth embodiment.

FIG. 9 is a diagram for explaining a configuration of a semiconductor device in a fifth embodiment.

FIG. 10 is a diagram for explaining a configuration of a semiconductor device in a sixth embodiment.

FIG. 11 is a diagram for explaining a configuration of a semiconductor device in a seventh embodiment.

FIG. 12 is a diagram for explaining a configuration of a semiconductor device in an eighth embodiment.

FIG. 13 is a diagram for explaining manufacturing of the semiconductor device in the eighth embodiment.

FIG. 14 is a diagram for explaining manufacturing of the semiconductor device in the eighth embodiment.

FIG. 15 is a diagram for explaining a configuration of a semiconductor device in a ninth embodiment.

FIG. 16 is a diagram for explaining a configuration of a semiconductor device in a 10th embodiment.

FIG. 17 is a diagram for explaining a configuration of a semiconductor device in an 11th embodiment.

FIG. 18 is a diagram for explaining a configuration of the semiconductor device in the 11th embodiment.

FIG. 19 is a diagram for explaining manufacturing of the semiconductor device in the 11th embodiment.

FIG. 20 is a diagram for explaining manufacturing of the semiconductor device in the 11th embodiment.

FIG. 21 is a diagram for explaining a configuration of a semiconductor device in a 12th embodiment.

FIG. 22 is a diagram for explaining a configuration of the semiconductor device in the 12th embodiment.

FIG. 23 is a diagram for explaining a configuration of a semiconductor device in a 13th embodiment.

FIG. 24 is a diagram for explaining a configuration of a semiconductor device in a 14th embodiment.

FIG. 25 is a diagram illustrating an example of an electronic device.

FIG. 26 is a view depicting an example of a schematic configuration of an endoscopic surgery system.

FIG. 27 is a block diagram depicting an example of a functional configuration of a camera head and a camera control unit (CCU).

FIG. 28 is a block diagram depicting an example of a schematic configuration of a vehicle control system.

FIG. 29 is an illustrative view illustrating an example of an installation position of an outside-vehicle information detecting section and an imaging section.

### MODE FOR CARRYING OUT THE INVENTION

Modes for carrying out the present technology (hereinafter, referred to as embodiments) is hereinafter described.

### First Embodiment

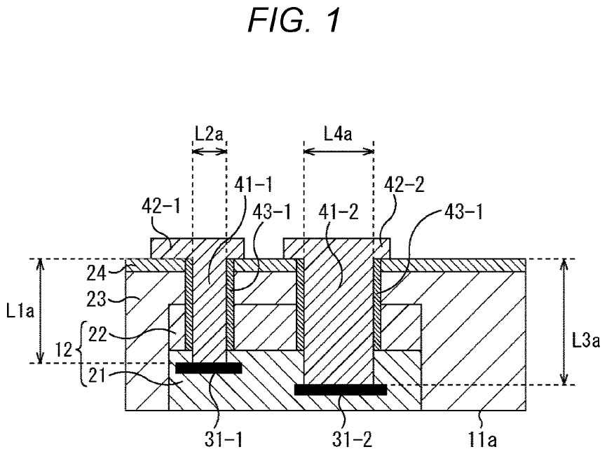

FIG. 1 is a diagram illustrating a configuration of an embodiment of a semiconductor device to which the present technology is applied. The semiconductor device 11 illustrated in FIG. 1 is referred to as a semiconductor device 11a as a first embodiment.

The semiconductor device 11a includes one chip 12. The chip 12 includes a wiring layer 21 and a semiconductor substrate 22. A semiconductor element is formed on the semiconductor substrate 22. The chip 12 is, for example, a signal processing circuit, a memory, an image sensor, or the like.

The semiconductor device 11a has a configuration in which the wiring layer 21, the semiconductor substrate 22, an insulating film 23, and a stopper film 24 are stacked in this order from the bottom in the drawing. Wiring 31-1 and wiring 31-2 are provided in the wiring layer 21. The wiring layer 21 may be a wiring layer formed in a pre-process of a semiconductor process, or may be a rewiring layer. The wiring 31-1 and the wiring 31-2 are formed in the wiring interlayer insulating film.

The insulating film 23 is formed on a side surface and an upper portion of the chip 12 including the wiring layer 21 and the semiconductor substrate 22. The insulating film 23 may be an inorganic film or an organic film. In a case where the insulating film 23 is constituted by an inorganic film, SiO2 (silicon dioxide), SiON (silicon oxynitride), SiN (silicon oxide), SiOC (silicon oxycarbide), or the like can be used as a material. In a case where the insulating film 23 is constituted by an organic film, a resin containing silicon, polyimide, acrylic, epoxy, or the like, or a molding material can be used.

The insulating film 23 may be constituted by a single material or may have a structure in which a plurality of materials is stacked. The stopper film 24 is formed on the insulating film 23. The insulating film 23 may be planarized after film formation, and a stopper film 24 capable of obtaining a high selectivity ratio with the insulating film 23 when dry etching is performed may be disposed thereon. The stopper film 24 may not be formed.

In a case where the insulating film 23 is SiO2, for example, SiN can be used as the stopper film 24. In a case where the insulating film 23 is an organic resin, for example, SiO2 can be used as the stopper film 24.

In the semiconductor device 11a illustrated in FIG. 1, two vias 41-1 and 41-2 are formed. The via 41-1 is connected to the wiring 31-1 in the wiring layer 21, and the via 41-2 is connected to the wiring 31-2 in the wiring layer 21. A liner film 43-1 is formed between the via 41-1 and the insulating film 23. Similarly, a liner film 43-2 is formed between the via 41-2 and the insulating film 23.

A rewiring line 42-1 is formed on the side of the via 41-1 opposite to the side to which the wiring 31-1 is connected (hereinafter, referred to as an upper surface), and is connected to the via 41-1. Similarly, a rewiring line 42-2 is formed on the upper surface side of the via 41-2 and is connected to the via 41-2. In the following description, in a case where it is not necessary to distinguish the via 41-1 and the via 41-2 individually, they are simply described as the via 41. Other parts will be described in a similar manner.

The via 41 and the rewiring line 42 can be constituted by copper (Cu), titanium (Ti), tantalum (Ta), aluminum (Al), tungsten (W), nickel (Ni), ruthenium (Ru), cobalt (Co), or the like. The via 41 and the rewiring line 42 may be constituted by the same material or may be constituted by different materials. In addition, a plurality of materials may be stacked. The rewiring line 42 is connected to a mounting substrate via, for example, a microbump, or connected to another stacked chip.

The liner film 43 may be an inorganic film or an organic film. In a case where the liner film 43 is constituted by an inorganic film, SiO2, SiON, SiN, SiOC, or the like can be used as a material. In a case where the liner film 43 is constituted by an organic film, a resin containing silicon, polyimide, acrylic, epoxy, or the like can be used. The liner film 43 may also be formed on the stopper film 24.

The diameters (widths) of the vias 41-1 and 41-2 are formed in sizes corresponding to the depths. The depth of the via 41-1 is defined as a depth L1a, and the depth of the via 41-2 is defined as a depth L3a. The depth of the via 41 is a size in the vertical direction (longitudinal direction in the drawing), and is a depth from a bonding surface where the rewiring line 42 and the via 41 are bonded. For example, the depth L1a of the via 41-1 is a distance from the bonding surface where the rewiring line 42-1 and the via 41-1 are bonded to the wiring 31-1. Similarly, the depth L3a of the via 41-2 is a distance from the bonding surface where the rewiring line 42-2 and the via 41-2 are bonded to the wiring 31-2.

The width of the via 41-1 is defined as a width L2a, and the width of the via 41-2 is defined as a width L4a. The width of the via 41 is a size in the horizontal direction (lateral direction in the drawing) and is a size corresponding to the opening diameter.

The via 41-1 and the via 41-2 are formed such that the aspect ratio between the depth L1a and the width L2a of the via 41-1 and the aspect ratio between the depth L3a and the width L4a of the via 41-2 are substantially the same value. In a case where the aspect ratio is depth:width=depth/width, the aspect ratio of the via 41-1 is (depth L1a/width L2a), and the aspect ratio of the via 41-2 is (depth L3a/width L4a).

The aspect ratio is adjusted to be substantially the same value. That is, the width L2a and the width L4a are set so that the relationship of (depth L1a/width L2a)=(depth L3a/width L4a) is satisfied.

The depth L1a of the via 41-1 is a length from the bonding surface to the wiring 31-1, and the depth L3a of the via 41-2 is a length from the bonding surface to the wiring 31-2. In the via 41-1 and the via 41-2, since the positions of the bonding surfaces are the same, the depth is set by the position of the wiring 31. In the semiconductor device 11a illustrated in FIG. 1, the wiring 31-1 is located at a shallower position than the wiring 31-2.

The relationship of the depth L1a of the via 41-1<the depth L3a of the via 41-2 is satisfied. In such a case, since the aspect ratio related to the via 41-1 and the aspect ratio related to the via 41-2 are adjusted to be substantially the same, the width L2a of the via 41-1 is formed to be smaller than the width L4a of the via 41-2. That is, the widths of the vias 41 are adjusted such that the relationship of the width L2a of the via 41-1<the width L4a of the via 41-2 is satisfied.

The width of the via 41 is adjusted such that the difference between the aspect ratio related to the via 41-1 and the aspect ratio related to the via 41-2 is, for example, 10% or less.

In this manner, by adjusting the width (diameter) of each via 41 so that the aspect ratios of the vias 41 are substantially the same, the following effects can be obtained. When a hole for forming the via 41 is processed by plasma etching, in general, a higher etching rate can be obtained as the diameter of the hole is larger. Therefore, the diameter can be increased as the via is connected to the lower wiring with a larger processing amount, and the manufacturing is facilitated. Therefore, integration of the vias 41, cost reduction, and yield can be improved.

### Second Embodiment

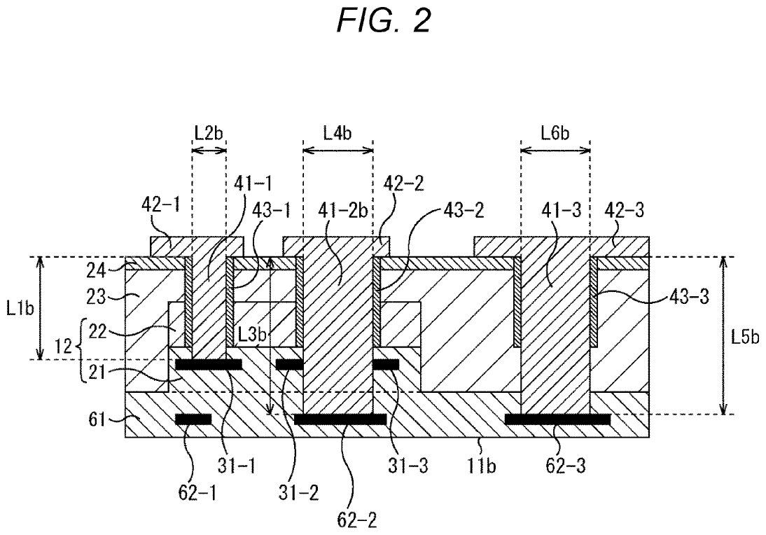

FIG. 2 is a diagram illustrating a configuration example of a semiconductor device 11b according to a second embodiment. Portions similar to those of the semiconductor device 11a in the first embodiment illustrated in FIG. 1 are denoted by similar reference numerals, and description thereof is omitted.

The semiconductor device 11b illustrated in FIG. 2 has a configuration in which a wiring layer 61, a via 41-3, and a portion related to the via 41-3 is added to the semiconductor device 11a illustrated in FIG. 1. The chip 12 is stacked on the wiring layer 61. Wiring 62-1, wiring 62-2, and wiring 62-3 are formed in the wiring layer 61.

A via 41-2b is connected to the wiring 31-2 and wiring 31-3 formed in the wiring layer 21 constituting the chip 12. Note that the wiring 31-2 and wiring 32-3 may be connected to form one wiring, or may be separate wirings. The via 41-2b is also connected to the wiring 62-2 of the wiring layer 61.

The via 41-3 is connected to the wiring 62-3 in the wiring layer 61. The via 41-3 is connected to a rewiring line 42-3 at a bonding surface. The via 41-3 is connected to the wiring 62-3 in the wiring layer 61 without penetrating the chip.

Diameters (widths) of the via 41-1, the via 41-2b, and the via 41-3 are formed in sizes corresponding to depths. The depth of the via 41-1 is defined as a depth L1b, the depth of the via 41-2b is defined as a depth L3b, and the depth of the via 41-3 is defined as a depth L5b. The width of the via 41-1 is a width L2b, the width of the via 41-2b is a width L4b, and the width of the via 41-3 is a width L6b.

The via 41-1, the via 41-2b, and the via 41-3 are formed such that the aspect ratio between the depth L1b and the width L2b of the via 41-1, the aspect ratio between the depth L3b and the width L4b of the via 41-2b, and the aspect ratio between the depth L5b and the width L6b of the via 41-3 are substantially the same. In a case where the aspect ratio is depth/width, the aspect ratio of the via 41-1 is (depth L1b/width L2b), the aspect ratio of the via 41-2b is (depth L3b/width L4b), and the aspect ratio of the via 41-3 is (depth L5b/width L6b).

The aspect ratio is adjusted to be substantially the same value. That is, the width L2b, the width L4b, and the width L6b are set so that the relationship of (depth L1b/width L2b)=(depth L3b/width L4b)=(depth L5b/width L6b) is satisfied.

The depth L1b of the via 41-1 is a length from the bonding surface to the wiring 31-1, the depth L3b of the via 41-2b is a length from the bonding surface to the wiring 62-2, and the depth L5b of the via 41-3 is a length from the bonding surface to the wiring 62-3. In the via 41-1, the via 41-2b, and the via 41-3, since the positions of the bonding surfaces are the same, the depth is set by the positions of the wiring 31-1, the wiring 62-2, and the wiring 62-3. In the semiconductor device 11b illustrated in FIG. 2, the wiring 31-1 is located at a shallower position than the wiring 62-2 and the wiring 62-3.

The relation of the depth L1b of the via 41-1<the depth L3b of the via 41-2b=the depth L5b of the via 41-3 is satisfied. In such a case, since the aspect ratio related to the via 41-1, the aspect ratio related to the via 41-2b, and the aspect ratio related to the via 41-3 are adjusted to be substantially the same, the width L2b of the via 41-1 is formed to be smaller than the width L4b of the via 41-2b and the width L6b of the via 41-3. That is, the widths of the vias 41 are adjusted such that the relationship of the width L2b of the via 41-1<the width L4b of the via 41-2 and the relationship of the width L2b of the via 41-1<the width L6b of the via 41-3 are satisfied.

The width of the via 41 is adjusted such that the difference between the aspect ratio related to the via 41-1 and the aspect ratio related to the via 41-2b (via 41-3) is, for example, within 10%.

As described above, by adjusting the width (diameter) of each via 41 so that the aspect ratios of the vias 41 become substantially the same, the via connected to the lower wiring (wiring layer) having a larger processing amount can have a larger diameter, and the manufacturing becomes easier. Therefore, integration of the vias 41, cost reduction, and yield can be improved.

The via 41-2b illustrated in FIG. 2 penetrates the chip 12 and is connected to the wiring 62-2 in the wiring layer 61. The via 41 penetrating the chip 12 (semiconductor substrate 22) in this manner is appropriately described as a through-via. The via 41-3 is connected to the wiring 62-3 in the wiring layer 61 without penetrating the chip 12. In this manner, the via 41 that does not penetrate the chip 12 (semiconductor substrate 22) will be appropriately described as a non-through-vias.

The via 41-2b which is a through-via and the via 41-3 which is a non-through-via have the same depth. As described above, in the case of having the same depth, it has been described that the diameters of the vias 41 are adjusted to be substantially the same in the above description. In a case where the vias 41 have the same depth but are a through-via and a non-through-via, the diameter of the non-through-via may be formed to be larger than the diameter of the through-via.

The ease of forming the through-via and the non-through-via is different. In general, since the insulating film 23 has a lower etching rate than the semiconductor substrate 22, it is possible to lower the difficulty by widening the path of the non-through-via in which the film to be processed is only the insulating film 23 than the through-via. Also in the process of forming the liner film 43 and the conductive film on the via 41, since the difficulty is determined by the aspect ratio, it is robust against the embedding failure. In consideration of such a difference, the diameter of the non-through-via may be formed to be larger than the diameter of the through-via.

In a case where the diameters of the through-vias and the non-through-vias having the same depth are made different from each other, in the semiconductor device 11b illustrated in FIG. 2, the relationship of the width L2b of the via 41-1<the width L4b of the via 41-2b<the width L6b of the via 41-3 is satisfied.

In the following description, a case where the diameters of the through-vias and the non-through-vias having the same depth are substantially the same will be described as an example, but the through-vias and the non-through-vias may be formed in different sizes.

### Third Embodiment

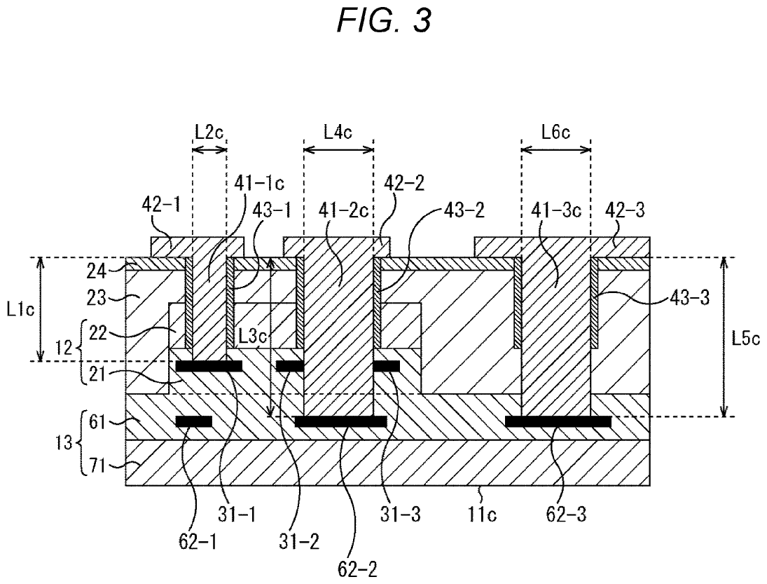

FIG. 3 is a diagram illustrating a configuration example of a semiconductor device 11c according to a third embodiment. Portions similar to those of the semiconductor device 11b in the second embodiment illustrated in FIG. 2 are denoted by similar reference numerals, and description thereof is omitted.

The semiconductor device 11c illustrated in FIG. 3 has a configuration in which a semiconductor substrate 71 is added to the semiconductor device 11b illustrated in FIG. 2. The semiconductor substrate 71 and the wiring layer 61 constitute a chip 13. The semiconductor device 11c has a configuration in which the chip 13 is stacked on the chip 12.

The chip 12 and the chip 13 are bonded with the wiring layers facing each other. The bonding method of the chip 12 and the chip 13 may be direct bonding of an insulating film or bonding via an adhesive.

The present technology can also be applied to a case of a configuration in which a plurality of chips is stacked as in the semiconductor device 11c. Although FIG. 3 illustrates a configuration in which two chips of the chip 12 and the chip 13 are stacked, the application range of the present technology is not limited to the stacking of two chips in the vertical direction, and the present technology can also be applied to stacking of two or more chips in the vertical direction. Although the configuration example in which one chip 12 is stacked on the chip 13 is illustrated in FIG. 3, a configuration in which a plurality of chips is stacked on the chip 13 may be adopted.

The configuration of the vias 41 of the semiconductor device 11c illustrated in FIG. 3 is similar to the configuration of the vias 41 of the semiconductor device 11b illustrated in FIG. 2. Since the aspect ratio of the via 41 is adjusted to be substantially the same, the width L2c, the width L4c, and the width L6c are set such that the relationship of (depth L1c/width L2c)=(depth L3c/width L4c)=(depth L5c/width L6c) is satisfied also in the semiconductor device 11c.

Also in the semiconductor device 11c illustrated in FIG. 3, the relationship of the depth L1c of a via 41-1c<the depth L3c of a via 41-2c=the depth L5c of a via 41-3c is satisfied. Therefore, since the aspect ratio related to the via 41-1c, the aspect ratio related to the via 41-2c, and the aspect ratio related to the via 41-3c are adjusted to be substantially the same, the width L2c of the via 41-1 is formed to be smaller than the width L4c of the via 41-2c and the width L6c of the via 41-3c. That is, the widths of the vias 41 are adjusted such that the relationship of the width L2c of the via 41-1c<the width L4c of the via 41-2c and the relationship of the width L2c of the via 41-1c<the width L6c of the via 41-3c are satisfied.

The width of the via 41 is adjusted such that the difference between the aspect ratio related to the via 41-1 and the aspect ratio related to the via 41-2c (via 41-3c) is, for example, within 10%.

As described above, also in the semiconductor device 11c having a configuration in which a plurality of chips is stacked, by adjusting the width (diameter) of each via 41 so that the aspect ratios of the vias 41 become substantially the same, the via connected to the lower wiring (wiring layer) having a larger processing amount can have a larger diameter, and the manufacturing becomes easy. Therefore, integration of the vias 41, cost reduction, and yield can be improved.

<Manufacture of Semiconductor Device 11c>

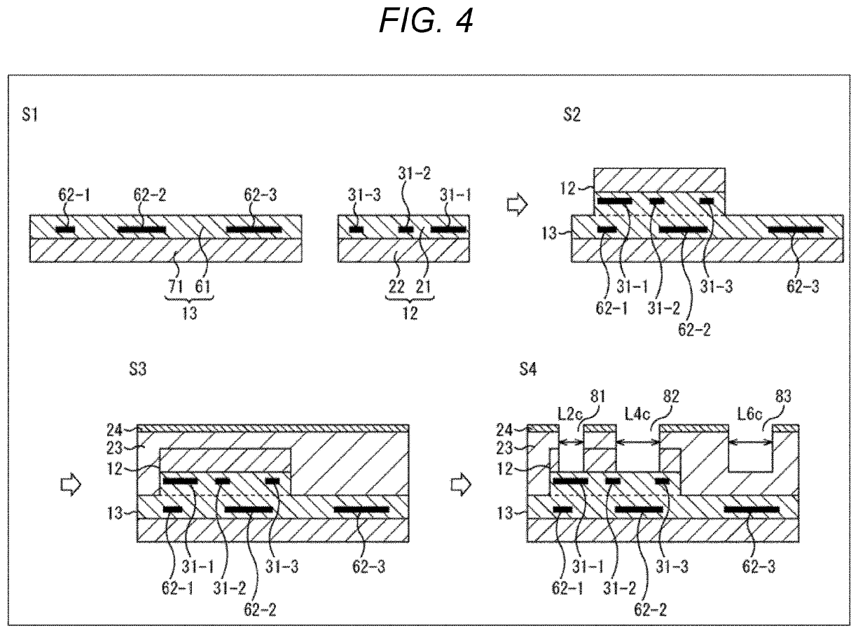

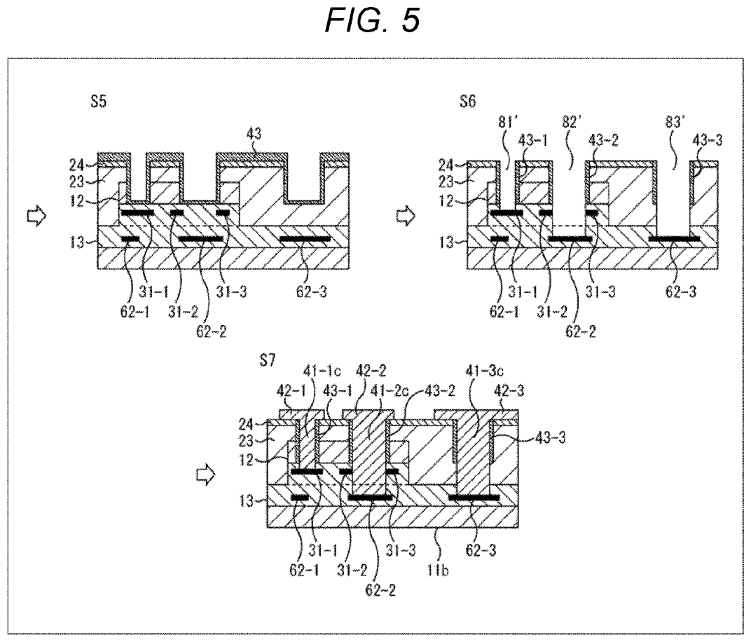

A process relating to the manufacturing of the semiconductor device 11c illustrated in FIG. 3 will be described with reference to FIGS. 4 and 5.

As illustrated in step S1 of FIG. 4, the chip 12 and the chip 13 are prepared. A semiconductor element is formed on the semiconductor substrate 22 of the chip 12, and wiring 31 is formed on the wiring layer 21. A semiconductor element is formed on the semiconductor substrate 71 of the chip 13, and wiring 62 is formed on the wiring layer 61. It is assumed that the chip 12 is in a state of being thinned or singulated, and the chip 13 is in a state of a wafer.

In step S2, the chip 12 is bonded onto the chip 13 in a wafer state by direct bonding.

In step S3, the insulating film 23 is formed around and on the upper portion of the chip 12 by, for example, a plasma-enhanced CVD (PE-CVD) method. After the insulating film 23 is formed, the surface is planarized by a grinder or chemical mechanical polishing (CMP). Thereafter, the stopper film 24 is formed by, for example, PE-CVD.

In step S4, holes 81 to 83 for forming the vias 41 are formed. The hole 81 is a hole for forming the via 41-1, and is formed to have a width L2c. Note that, since the liner film 43 is formed in the hole 81 as described later, the via 41-1 having the width L2c is formed to be large by the film thickness of the liner film 43. Note that, in the following description, for example, it is described that the width of the hole 81 is formed to be the width L2c, but the width L2c is a width in consideration of the film thickness of the liner film 43.

In step S4, the hole 81, the hole 82, and the hole 83 are formed by lithography and plasma etching. The hole 81 is formed such that the width of the hole 81 is the width L2c, the hole 82 is formed such that the width of the hole 82 is the width L4c, and the hole 83 is formed such that the width of the hole 83 is the width L6c. As described above, the width L2c, the width L4c, and the width L6c satisfy the relationship of width L2c<width L4c=width L6c or width L2c<width L4c<width L6c.

The depths of the holes 81 to 83 are the same in step S4, and are processed up to the upper surface of the semiconductor substrate 22. That is, in step S4, the insulating film 23 is etched up to the upper surface of the semiconductor substrate 22.

As an example, specific numerical values will be described. In a case where the thickness is 30 um from the surface of the insulating film 23 to the wiring 31-1 of the chip 12, the width L2c of the hole 81 for forming the via 41-1 is 6 um. In a case where the thickness is 40 um from the surface of the insulating film 23 to the wiring 62-2 of the chip 13, the width L4c of the hole 82 for forming the via 41-2b is 8 um. The width L6c of the hole 83 for forming the via 41-3 is 8 um.

In this case, the aspect ratio of each of the vias 41-1 and 41-2b and the via 41-3 to be formed is 5. By equalizing the aspect ratio in this manner, the manufacturing difficulty can be alleviated. Note that the aspect ratio of the via 41 is, for example, about 1 to 20.

In step S5 (FIG. 5), the liner film 43 of SiO2 is formed by, for example, PE-CVD. In step S5, a film is also formed on a portion other than the inner side surfaces of the holes 81 to 83 to be finally left as the liner film 43. The liner film 43 is formed on the stopper film 24, the inner side surfaces of the holes 81 to 83, and the bottom surfaces of the holes 81 to 83. The film formation coverage is adjusted such that the thickness of the liner film 43 formed on the stopper film 24 is larger than the thickness of the liner film 43 formed on the bottom surfaces of the holes 81 to 83. As an example, the film is formed so that the minimum film thickness of the side surface portion of the semiconductor substrate 22 of the holes 81 to 83 is 50 nm or more.

In step S6, the entire surface is etched back by, for example, dry etching, and processed until the wiring 31-1, the wiring 62-2, and the wiring 62-3 are exposed. Since the stopper film 24 is formed on the surface portion, it is possible to prevent the insulating film 23 from being processed and the semiconductor substrate 22 from being exposed.

In step S7, a conductive film is formed in each of the holes 81 to 83, whereby the via 41-1, the via 41-2b, and the via 41-3 are formed. As an example, a stacked structure using Ti as a barrier metal and Cu as a conductive film may be formed.

When the via 41-1, the via 41-2b, and the via 41-3 are formed, a film is formed on the surface, patterning is performed by lithography and etching, and rewiring lines 42-1 to 42-3 are formed. The method for forming the rewiring line may be a subtractive method or a semi-additive method. Although the shape is different from the shape of the rewiring line 42 illustrated in the portion of step S7, the rewiring line 42 may be formed by applying a damascene method.

In such a process, the semiconductor device 11c illustrated in FIG. 3 is manufactured. Note that the manufacturing process illustrated here is an example, and is not a description indicating limitation. It is also possible to appropriately change the order of the steps or to perform film formation, processing, or the like by applying a method other than the method described here.

### Fourth Embodiment

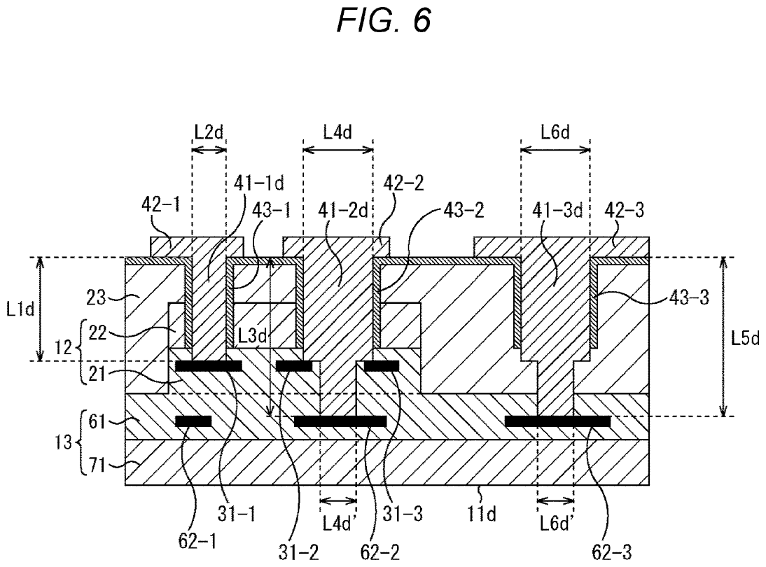

FIG. 6 is a diagram illustrating a configuration example of a semiconductor device 11d according to a fourth embodiment. Portions similar to those of the semiconductor device 11c in the third embodiment illustrated in FIG. 3 are denoted by similar reference numerals, and description thereof is omitted.

In the following embodiment, a case of being combined with the third embodiment will be described as an example, but the present invention can be implemented in combination with the first embodiment or in combination with the second embodiment.

The semiconductor device 11d illustrated in FIG. 3 has a similar configuration to the semiconductor device 11c illustrated in FIG. 3, but the shape of the via 41 is different. A via 41-2d and a via 41-3d of the semiconductor device 11d have shapes in which diameters (widths) of the vias change in the middle. A width L4d of the via 41-2d from the upper surface of the semiconductor device 11d to the wiring layer 21 of the chip 12 and a width L4d′ of the via 41-2d from the upper surface of the wiring layer 21 to the wiring 62-2 are formed with different widths.

In the via 41-3d, similarly to the via 41-2d, the width L6d of the via 41-2d from the upper surface of the semiconductor device 11d to the position corresponding to the wiring layer 21 of the chip 12 and the width L6d′ of the via 41-3d from the position corresponding to the upper surface of the wiring layer 21 to the wiring 62-3 are formed with different widths.

As described above, the semiconductor device 11d has a structure in which the diameter (width) of the via 41 changes on the upper surface of the wiring layer 21 of the chip 12, in other words, in the vicinity of the bottom surface of the semiconductor substrate 22. With such a structure, it is possible to avoid excessive over-etching of the wiring 31 of the chip 12 when processing the via 41, and thus, it is possible to suppress deterioration of device characteristics due to metal scattering, an open defect due to wiring penetration, and fluctuation of the semiconductor element of the chip 12 due to charging damage.

Since excessive over-etching can be avoided with respect to the wiring 31 of the chip 12, the stopper film 24 may not be formed. FIG. 6 illustrates a configuration of the semiconductor device 11d in a case where the stopper film 24 is not formed.

In the configuration of the vias 41 of the semiconductor device 11d illustrated in FIG. 6, similarly to the vias 41 of the semiconductor device 11c illustrated in FIG. 3, the aspect ratios of the vias 41 are the same. Also in the semiconductor device 11d, the width L2d, the width L4d, and the width L6d are set so that the relationship of (depth L1d/width L2d)=(depth L3d/width L4d)=(depth L5d/width L6d) is satisfied.

Also in the semiconductor device 11d illustrated in FIG. 6, the relationship of the depth L1d of a via 41-1d<the depth L3d of the via 41-2d=the depth L5d of the via 41-3d is satisfied. Therefore, since the aspect ratio related to the via 41-1d, the aspect ratio related to the via 41-2d, and the aspect ratio related to the via 41-3d are adjusted to be substantially the same, the width L2d of the via 41-1d is formed to be smaller than the width L4d of the via 41-2d and the width L6d of the via 41-3d. That is, the widths of the vias 41 are adjusted such that the relationship of the width L2d of the via 41-1d<the width L4d of the via 41-2d and the relationship of the width L2d of the via 41-1d<the width L6d of the via 41-3d are satisfied.

As described above, also in the semiconductor device 11d having a configuration in which a plurality of chips is stacked, by adjusting the width (diameter) of each via 41 so that the aspect ratios of the vias 41 become substantially the same, the via connected to the lower wiring (wiring layer) having a larger processing amount can have a larger diameter, and the manufacturing becomes easy. Therefore, integration of the vias 41, cost reduction, and yield can be improved.

<Manufacture of Semiconductor Device 11d>

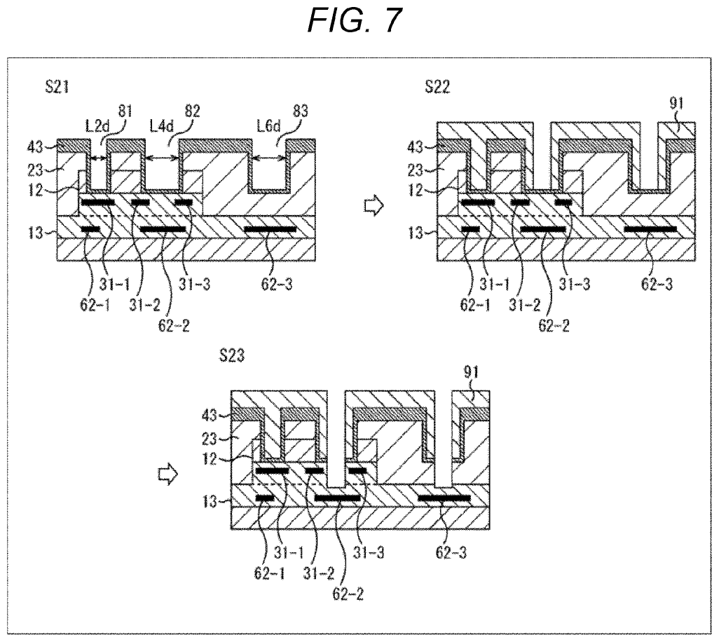

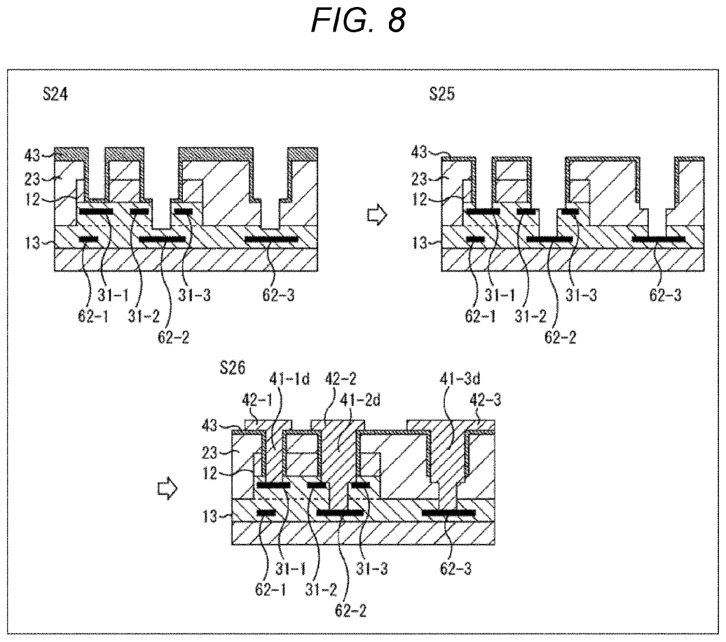

A process relating to the manufacturing of the semiconductor device 11d illustrated in FIG. 4 will be described with reference to FIGS. 7 and 8.

Step S21 is a state illustrated in step S5 of FIG. 5, and is a state in which the holes 81 to 83 are formed. Through the steps S1 to S4, (a part of) the semiconductor device 11d in the state illustrated in step S21 is formed. Note that, since it is not necessary to form the stopper film 24, step S3 (FIG. 4) can be omitted.

In step S22, a resist mask 91 having a smaller diameter than the holes 82 and 83 is formed in a portion to be the via 41-2d and the via 41-3d by lithography, for example. The diameter of the resist mask 91 is smaller than the interval between the wiring 31-2 and the wiring 31-3 of the wiring layer 21 of the chip 12.

In step S23, the insulating film 23 in the hole 82 and the hole 83 is processed by, for example, dry etching. Processing is performed until just before the wiring 62 is exposed, and adjustment is performed so that the residual film on the wiring to which each via 41 is connected becomes similar. The residual film is the wiring layer 21 between the bottom surface of the hole 81 and the upper surface of the wiring 31-1, the wiring layer 61 between the bottom surface of the hole 82 and the upper surface of the wiring 62-2, and the wiring layer 61 between the bottom surface of the hole 83 and the upper surface of the wiring 62-3, and processing is performed in which the thicknesses of these residual films are adjusted to be similar.

In step S24 (FIG. 8), the resist mask 91 is removed by ashing or cleaning, for example.

In step S25, the entire surface is etched back, and the wiring 31 (62) of each via 41 is exposed. At this time, by adjusting the residual films on the wiring 31-1, the wiring 62-2, and the wiring 62-3 to be equal, it is possible to prevent the wiring connected to the specific via 41 from being excessively etched.

In step S26, the via 41-1, the via 41-2d, and the via 41-3d are formed, and the rewiring lines 42-1 to 42-3 are formed. Step S25 is a step similar to step S7 (FIG. 5).

In such a process, the semiconductor device 11d illustrated in FIG. 6 is manufactured. Note that the manufacturing process illustrated here is an example, and is not a description indicating limitation. It is also possible to appropriately change the order of the steps or to perform film formation, processing, or the like by applying a method other than the method described here.

### Fifth Embodiment

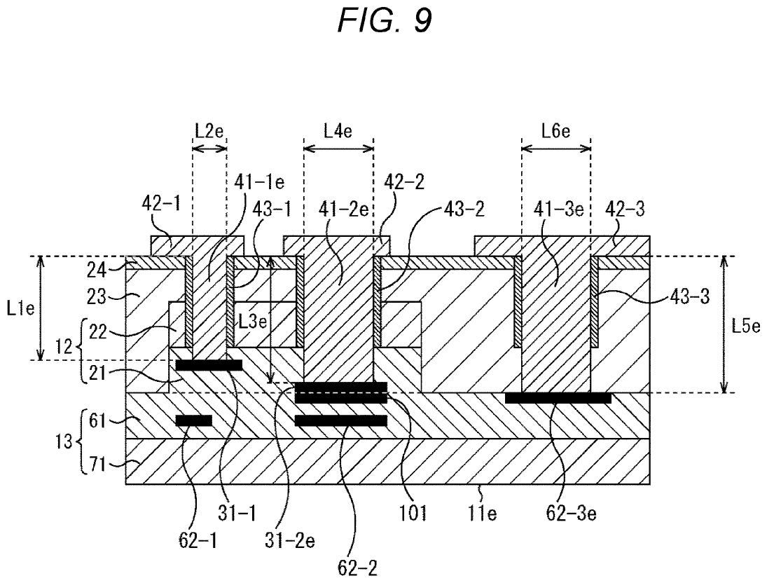

FIG. 9 is a diagram illustrating a configuration example of a semiconductor device 11e according to a fifth embodiment. Portions similar to those of the semiconductor device 11c in the third embodiment illustrated in FIG. 3 are denoted by similar reference numerals, and description thereof is omitted.

The semiconductor device 11e illustrated in FIG. 9 is different from the semiconductor device 11c illustrated in FIG. 3 in that wirings in a wiring layer are bonded so as to be electrically connected to each other, and the other points are similar.

In the semiconductor device 11e, wiring 31-2e of the wiring layer 21 of the chip 12 is formed on the bottom surface side of the wiring layer 21 (the surface side facing the surface bonded to the semiconductor substrate 22), and is bonded to wiring 101 formed on the upper surface side of the wiring layer 61 of the chip 13 (the surface side facing the surface bonded to the semiconductor substrate 71). A via 41-2e is connected to wiring 31-2e.

Wiring 62-3e of the wiring layer 61 of the chip 13 is formed on the upper surface side of the wiring layer 61. A via 41-3e is connected to the wiring 62-3e.

By configuring the chip 12 and the chip 13 such that the wirings are directly bonded to each other, it is possible to configure such that the chip 12 and the chip 13 are simultaneously connected only by configuring the via 41-2e to be connected to the wiring 31-2e bonded to the wiring 101. The structure of the via 41-2e can be simplified. The depth of the via 41-2e and the via 41-3e connected to the chip 13 can be shortened, and a configuration advantageous for high integration of the semiconductor device 11e can be obtained.

In the configuration of the vias 41 of the semiconductor device 11e illustrated in FIG. 9, similarly to the vias 41 of the semiconductor device 11c illustrated in FIG. 3, the aspect ratios of the vias 41 are the same. Also in the semiconductor device 11e, the width L2e, the width L4e, and the width L6e are set so that the relationship of (depth Lie/width L2e)=(depth L3e/width L4e)=(depth L5e/width L6e) is satisfied.

In the semiconductor device 11e illustrated in FIG. 9, the relationship of the depth Lie of a via 41-1e<the depth L3e of the via 41-2e<the depth L5e of the via 41-3e is satisfied. The depth L3e of the via 41-2e is shorter than the depth L5e of the via 41-3 by the film thickness of the wiring 31-2e.

Since the aspect ratio related to the via 41-le, the aspect ratio related to the via 41-2e, and the aspect ratio related to the via 41-3e are adjusted to be substantially the same, the width L2e of the via 41-1e is smaller than the width L4e of the via 41-2e, and the width L4e of the via 41-2e is formed to be smaller than the width L6e of the via 41-3e. That is, the widths of the vias 41 are adjusted such that the relationship of the width L2e of the via 41-1e<the width L4e of the via 41-2e<the width L6e of the via 41-3e is satisfied.

As described above, also in the semiconductor device 11e having a configuration in which a plurality of chips is stacked and the chips are directly connected to each other by the wirings of the wiring layer, by adjusting the width (diameter) of each via 41 so that the aspect ratios of the vias 41 become substantially the same, the via connected to the lower wiring (wiring layer) having a larger processing amount can be made larger in diameter, and the manufacturing becomes easier. Therefore, integration of the vias 41, cost reduction, and yield can be improved.

### Sixth Embodiment

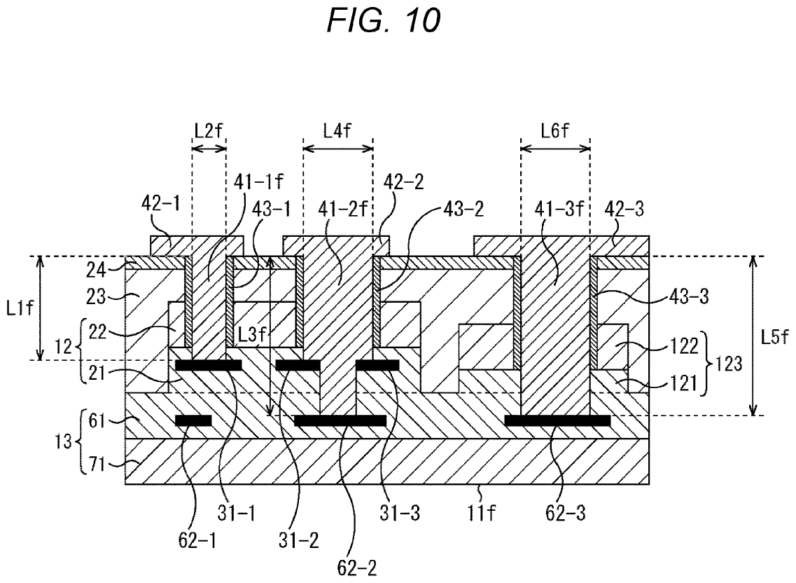

FIG. 10 is a diagram illustrating a configuration example of a semiconductor device 11f according to a sixth embodiment. Portions similar to those of the semiconductor device 11c in the third embodiment illustrated in FIG. 3 are denoted by similar reference numerals, and description thereof is omitted.

The semiconductor device 11f illustrated in FIG. 10 is different in that a dummy chip is stacked on the semiconductor device 11c illustrated in FIG. 3, and the other points are similar. The via 41-3 of the semiconductor device 11c illustrated in FIG. 3 penetrates the insulating film 23, but the semiconductor device 11f illustrated in FIG. 10 penetrates a dummy chip 123.

The semiconductor device 11f illustrated in FIG. 10 has a configuration in which the chip 12 and the dummy chip 123 are stacked on the chip 13. The dummy chip 123 includes a wiring layer 121 and a semiconductor substrate 122.

The dummy chip 123 preferably has a similar structure to the chip 12 and is constituted by the same material as the chip 12. In FIG. 10, the dummy chip 123 is formed to be smaller than the chip 12, but the thickness of the dummy chip 123 is preferably about the same as that of the chip 12. The bonding layer of the dummy chip 123 is also preferably constituted by the same material as the bonding layer of the chip 12.

A via 41-3f penetrates the dummy chip 123 and is connected to the wiring 62-3 in the wiring layer 61 of the chip 13. In the semiconductor device 11c illustrated in FIG. 3, stress applied to the chip 13 is different due to a difference in physical properties of materials of the chip 12 and the insulating film 23. In the semiconductor device 11f illustrated in FIG. 10, since the dummy chip 123 is arranged, stress applied to the chip 13 can be reduced. In addition, planarization of the insulating film 23 is facilitated.

In the semiconductor device 11c illustrated in FIG. 3, when forming the via 41-3 connected to the chip 13 without penetrating the chip 12, it is necessary to process a large number of insulating films 23 having a low etching rate. In the semiconductor device 11f illustrated in FIG. 10, since the dummy chip 123 is arranged, the via 41-3f can have a via structure penetrating the dummy chip 123, and the manufacturing is facilitated.

In the configuration of the vias 41 of the semiconductor device 11f illustrated in FIG. 10, similarly to the vias 41 of the semiconductor device 11c illustrated in FIG. 3, the aspect ratios of the vias 41 are the same. Also in the semiconductor device 11f, the width L2f, the width L4f, and the width L6f are set so that the relationship of (depth L1f/width L2f)=(depth L3f/width L4f)=(depth L5f/width L6f) is satisfied.

Also in the semiconductor device 11f illustrated in FIG. 10, the relationship of the depth L1f of a via 41-1f<the depth L3f of a via 41-2f=the depth L5f of the via 41-3f is satisfied. Therefore, since the aspect ratio related to the via 41-1f, the aspect ratio related to the via 41-2f, and the aspect ratio related to the via 41-3f are adjusted to be substantially the same, the width L2f of the via 41-1f is formed to be smaller than the width L4f of the via 41-2f and the width L6f of the via 41-3f. That is, the widths of the vias 41 are adjusted such that the relationship of the width L2f of the via 41-1f<the width L4f of the via 41-2f and the relationship of the width L2f of the via 41-1f<the width L6f of the via 41-3f are satisfied.

As described above, also in the semiconductor device 11f having a configuration in which a plurality of chips is stacked, by adjusting the width (diameter) of each via 41 so that the aspect ratios of the vias 41 become substantially the same, the via connected to the lower wiring (wiring layer) having a larger processing amount can have a larger diameter, and the manufacturing becomes easy. Therefore, integration of the vias 41, cost reduction, and yield can be improved.

### Seventh Embodiment

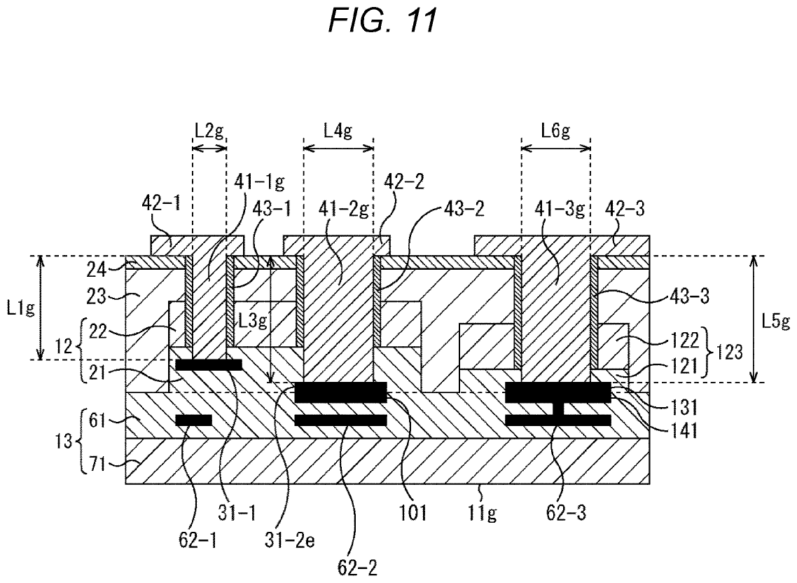

FIG. 11 is a diagram illustrating a configuration example of a semiconductor device 11g according to a seventh embodiment. Portions similar to those of the semiconductor device 11f in the sixth embodiment illustrated in FIG. 10 are denoted by similar reference numerals, and description thereof is omitted.

The semiconductor device 11g illustrated in FIG. 11 is different in that wiring 131 is provided in the wiring layer 121 of the dummy chip 123 of the semiconductor device 11f illustrated in FIG. 10. In addition, the semiconductor device 11g illustrated in FIG. 11 has a configuration in which the wirings formed in the wiring layer are directly bonded to each other, so that the chips are connected to each other, which is similar to the semiconductor device 11e illustrated in FIG. 9.

In the semiconductor device 11g illustrated in FIG. 11, the wiring 131 formed in the wiring layer 121 of the dummy chip 123 is bonded to wiring 141 formed in the wiring layer 61 of the chip 13. The wiring 141 is connected to the wiring 62-3 in the wiring layer 61.

With such a configuration, the depth of a via 41-3g can be shortened, and a configuration advantageous for high integration can be obtained.

In the configuration of the vias 41 of the semiconductor device 11g illustrated in FIG. 11, similarly to the vias 41 of the semiconductor device 11c illustrated in FIG. 3, the aspect ratios of the vias 41 are the same. Also in the semiconductor device 11g, the width L2g, the width L4g, and the width L6g are set so that the relationship of (depth L1g/width L2g)=(depth L3g/width L4g)=(depth L5g/width L6g) is satisfied.

In the semiconductor device 11g illustrated in FIG. 11, the relationship of the depth L1g of a via 41-1g<the depth L3g of a via 41-2g=the depth L5g of the via 41-3g is satisfied. Therefore, since the aspect ratio related to the via 41-1g, the aspect ratio related to the via 41-2g, and the aspect ratio related to the via 41-3g are adjusted to be substantially the same, the width L2g of the via 41-1g is formed to be smaller than the width L4g of the via 41-2g and the width L6g of the via 41-3g. That is, the widths of the vias 41 are adjusted such that the relationship of the width L2g of the via 41-1g<the width L4g of the via 41-2g and the relationship of the width L2g of the via 41-1g<the width L6g of the via 41-3g are satisfied.

As described above, also in the semiconductor device 11g having a configuration in which a plurality of chips is stacked, by adjusting the width (diameter) of each via 41 so that the aspect ratios of the vias 41 become substantially the same, the via connected to the lower wiring (wiring layer) having a larger processing amount can have a larger diameter, and the manufacturing becomes easy. Therefore, integration of the vias 41, cost reduction, and yield can be improved.

### Eighth Embodiment

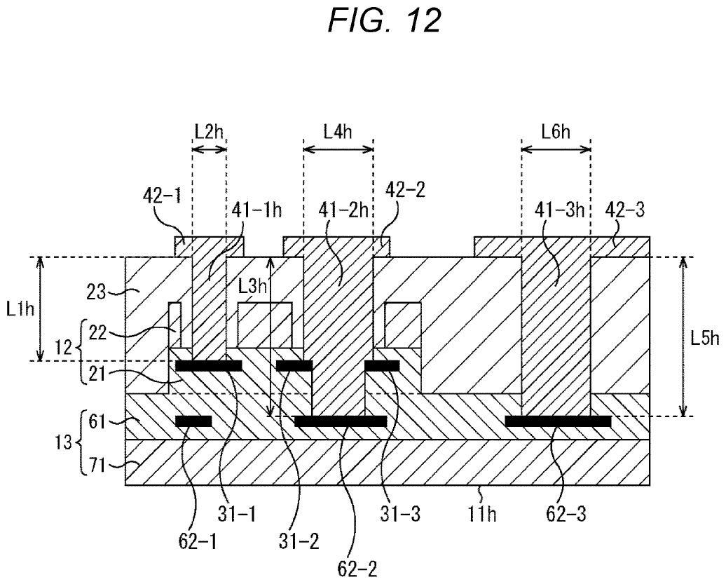

FIG. 12 is a diagram illustrating a configuration example of a semiconductor device 11h according to an eighth embodiment. Portions similar to those of the semiconductor device 11c in the third embodiment illustrated in FIG. 3 are denoted by similar reference numerals, and description thereof is omitted.

The semiconductor device 11h illustrated in FIG. 11 is different from the semiconductor device 11c illustrated in FIG. 3 in that the liner film 43 is removed, and the other points are similar. In the semiconductor device 11h illustrated in FIG. 11, the insulating film 23 is formed around a via 41-1h, a via 41-2h, and a via 41-3h instead of the liner film 43.

In the semiconductor device 11h, a film corresponding to the liner film 43 around the via 41-1h, the via 41-2h, and the via 41-3h is formed using the same material as the insulating film 23 formed on the side surface and the upper surface of the chip 12. In other words, the insulating film 23 is formed on the side surface of each of the via 41-1h, the via 41-2h, and the via 41-3h.

According to the semiconductor device 11h, since there is no liner film 43, it is possible to avoid occurrence of reliability failure such as occurrence of a crack in the liner film 43 due to a difference in linear expansion coefficient between the insulating film 23 and the liner film 43. At the time of manufacturing the semiconductor device 11h, the insulating film 23 and the liner film 43 (corresponding films) can be formed at the same time, and the number of processes can be reduced and the manufacturing process can be simplified.

The insulating film 23 used as a substitute for the liner film 43 is preferably formed by applying or laminating a photosensitive insulating resin having a skeleton of silicon, polyimide, acrylic, epoxy, or the like. As the insulating film 23, an inorganic film such as SiO2, SiON, SiN, or SiOC can also be used.

In the configuration of the vias 41 of the semiconductor device 11h illustrated in FIG. 12, similarly to the vias 41 of the semiconductor device 11c illustrated in FIG. 3, the aspect ratios of the vias 41 are the same. Also in the semiconductor device 11h, the width L2h, the width L4h, and the width L6h are set so that the relationship of (depth L1h/width L2h)=(depth L3h/width L4h)=(depth L5h/width L6h) is satisfied.

Also in the semiconductor device 11h illustrated in FIG. 12, the relationship of the depth L1h of the via 41-1h<the depth L3h of the via 41-2h=the depth L5h of the via 41-3h is satisfied. Therefore, since the aspect ratio related to the via 41-1h, the aspect ratio related to the via 41-2h, and the aspect ratio related to the via 41-3h are adjusted to be substantially the same, the width L2h of the via 41-1 is formed to be smaller than the width L4h of the via 41-2h and the width L6h of the via 41-3h. That is, the widths of the vias 41 are adjusted such that the relationship of the width L2h of the via 41-1h<the width L4h of the via 41-2h and the relationship of the width L2h of the via 41-1h<the width L6h of the via 41-3h are satisfied.

As described above, also in the semiconductor device 11h having the configuration in which the chips are stacked, by adjusting the width (diameter) of each via 41 so that the aspect ratios of the vias 41 become substantially the same, the via connected to the lower wiring (wiring layer) having a larger processing amount can have a larger diameter, and the manufacturing becomes easy. Therefore, integration of the vias 41, cost reduction, and yield can be improved.

<Manufacture of Semiconductor Device 11h>

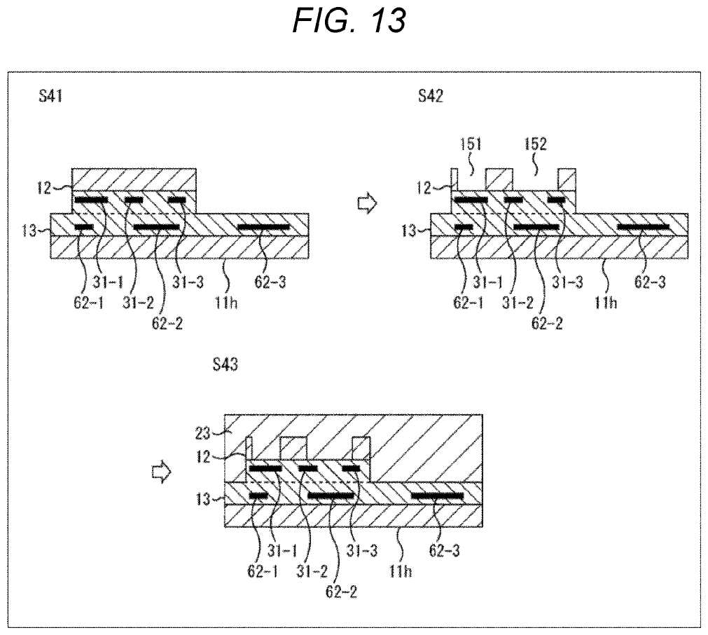

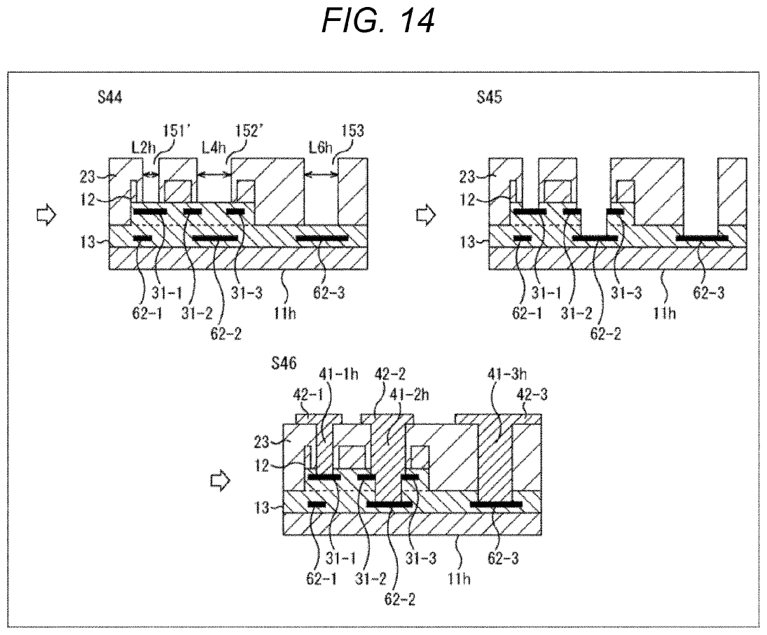

A process relating to the manufacturing of the semiconductor device 11h illustrated in FIG. 12 will be described with reference to FIGS. 13 and 14.

Step S41 is the state illustrated in step S2 of FIG. 4, and is a state in which the chip 12 on which the wirings 31-1 to 31-3 are formed is stacked on the chip 13 on which the wirings 62-1 to 62-3 are formed.

In step S42, a hole 151 and a hole 152 for forming the via 41-1h and the via 41-2h are formed by, for example, lithography and dry etching.

In step S43, a photosensitive epoxy resin is applied so as to fill the side surface and the upper surface of the chip 12, the upper surface of the chip 13, and the holes 151 and 152 formed in the chip 12. After the application, a planarization treatment by a grinder or CMP is performed as necessary. The applied epoxy resin is used as the insulating film 23, and is also used as the insulating film 23 instead of the liner film 43.

In step S44 (FIG. 14), a hole 151′, a hole 152′, and a hole 153 are developed in the photosensitive insulating film 23 by lithography, and a permanent film is formed by curing. The hole 151′ is a hole in which the via 41-1h is formed, and its width is a width L2h. The hole 152′ is a hole in which the via 41-2h is formed, and its width is a width L4h. The hole 153 is a hole in which the via 41-3h is formed, and its width is a width L6h.

In step S45, wiring is processed. Since the via 41-1h is connected to the wiring 31-1, the wiring layer 21 is processed such that the wiring 31-1 is exposed. Since the via 41-2h is connected to the wiring 62-2, the wiring layer 21 and the wiring layer 61 are processed such that the wiring 62-2 is exposed. Since the via 41-3h is connected to the wiring 62-3, the insulating film 23 is processed such that the wiring 62-3 is exposed.

In step S46, the via 41-1h, the via 41-2h, and the via 41-3h are formed, and the rewiring line 42-1, the rewiring line 42-2, and the rewiring line 42-3 are formed. The process of step S46 can be performed similarly to step S7 (FIG. 5).

In such a process, the semiconductor device 11h illustrated in FIG. 12 is manufactured. Note that the manufacturing process illustrated here is an example, and is not a description indicating limitation. It is also possible to appropriately change the order of the steps or to perform film formation, processing, or the like by applying a method other than the method described here.

### Ninth Embodiment

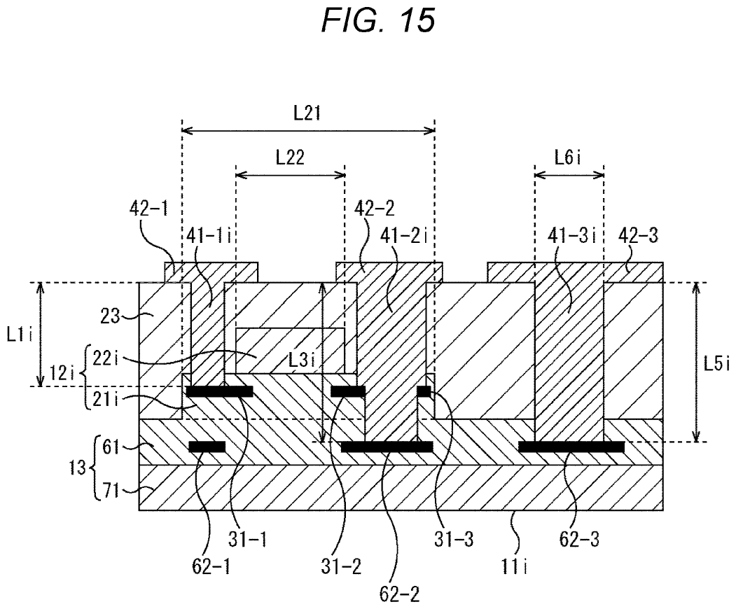

FIG. 15 is a diagram illustrating a configuration example of a semiconductor device 11i according to a ninth embodiment. Portions similar to those of the semiconductor device 11c in the third embodiment illustrated in FIG. 3 are denoted by similar reference numerals, and description thereof is omitted.

In the semiconductor device 11i illustrated in FIG. 15, the shape of a chip 12h is different from that of the chip 12 of the semiconductor device 11c illustrated in FIG. 3, and the other points are similar. In a chip 12i of the semiconductor device 11i illustrated in FIG. 15, wiring layer 21i and a semiconductor substrate 22i are different in size. In a case where the width of the wiring layer 21i is the width L21 and the width of the semiconductor substrate 22i is the width L22, a relationship of width L21>width L22 is established.

A difference is provided between the area of the wiring layer 21i and the area of the semiconductor substrate 22i, and the via 41 is formed in a region of the difference. A via 41-li is connected to the wiring 31-1 of the wiring layer 21i in a region of the wiring layer 21i to which the semiconductor substrate 22i is not bonded. The via 41-2i is connected to the wiring 31-2 and the wiring 31-3 of the wiring layer 21i in a region of the wiring layer 21i to which the semiconductor substrate 22i is not bonded.

By adopting a configuration in which the via 41-1i and a via 41-2i are connected to the wiring 31 in the wiring layer 21i without providing a through-hole in the semiconductor substrate 22i, the process of forming the through-hole can be omitted, and the process can be simplified. The semiconductor substrate 22i can be easily made smaller than the wiring layer 21i by, for example, isotropically wet etching the semiconductor substrate 22i after bonding the chip 12 and the chip 13, or the like

The semiconductor device 11i can have a configuration in which the liner film 43 is removed. Therefore, the process of forming the liner film 43 can be reduced, and the number of manufacturing processes can be reduced.

In the configuration of the vias 41 of the semiconductor device 11i illustrated in FIG. 15, similarly to the vias 41 of the semiconductor device 11c illustrated in FIG. 3, the aspect ratios of the vias 41 are the same. Also in the semiconductor device 11i, the width L2i, the width L4i, and the width L6i are set so that the relationship of (depth L1i/width L2i)=(depth L3i/width L4i)=(depth L5i/width L6i) is satisfied.

Also in the semiconductor device 11i illustrated in FIG. 15, the relationship of the depth L1i of the via 41-1i<the depth L3i of the via 41-2i=the depth L5i of the via 41-3i is satisfied. Therefore, since the aspect ratio related to the via 41-1i, the aspect ratio related to the via 41-2i, and the aspect ratio related to the via 41-3i are adjusted to be substantially the same, the width L2i of the via 41-1 is formed to be smaller than the width L4i of the via 41-2i and the width L6i of the via 41-3i. That is, the widths of the vias 41 are adjusted such that the relationship of the width L2i of the via 41-1i<the width L4i of the via 41-2i and the relationship of the width L2i of the via 41-1i<the width L6i of the via 41-3i are satisfied.

As described above, also in the semiconductor device 11i having the configuration in which the chips are stacked, by adjusting the width (diameter) of each via 41 so that the aspect ratios of the vias 41 become substantially the same, the via connected to the lower wiring (wiring layer) having a larger processing amount can have a larger diameter, and the manufacturing becomes easy. By forming the via 41 at a position where the semiconductor substrate does not need to be processed, the number of manufacturing processes can be reduced. Therefore, integration of the vias 41, cost reduction, and yield can be improved.

<10th Embodiment>

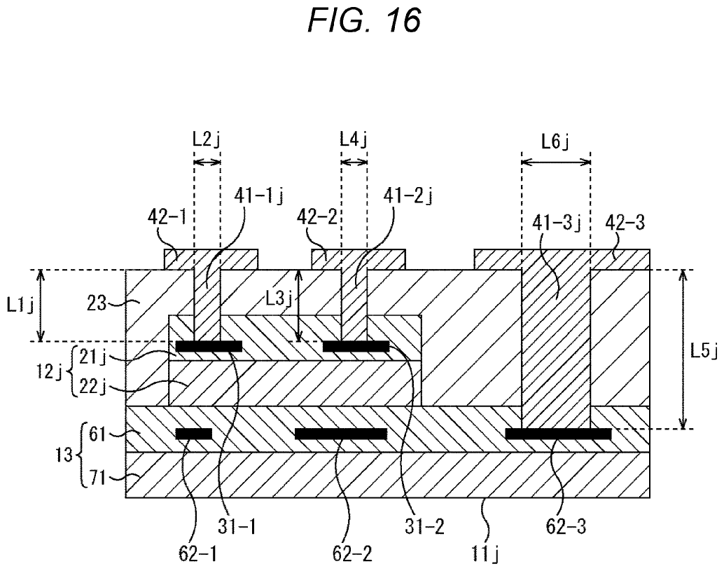

FIG. 16 is a diagram illustrating a configuration example of a semiconductor device 11j according to a 10th embodiment. Portions similar to those of the semiconductor device 11c in the third embodiment illustrated in FIG. 3 are denoted by similar reference numerals, and description thereof is omitted.

The semiconductor device 11j illustrated in FIG. 16 is different from the semiconductor device 11c illustrated in FIG. 3 in the manner of bonding the chip 12j and the chip 13, and the other points are similar. In the semiconductor device 11j illustrated in FIG. 16, a wiring layer 21j of a chip 12j is located on the upper surface side of the semiconductor device 11j, and a semiconductor substrate 22j of the chip 12j and the wiring layer 61 of the chip 13 are bonded.

By adopting a configuration in which the semiconductor substrate 22j of the chip 12j and the wiring layer 61 of the chip 13 are bonded, it is not necessary to form a through-hole for forming the via 41 in the semiconductor substrate 22j of the chip 12j, and thus, it is possible to reduce the process of forming the through-hole in the semiconductor substrate 22j. Since it is not necessary to provide a through-hole in the semiconductor substrate 22j, it is also possible to adopt a configuration in which a semiconductor element is disposed on the entire surface of the semiconductor substrate 22j.

A via 41-1j and a via 41-2j connected to the wiring 31 in the chip 12j can be formed shorter (shallower) than the via 41-1c and the via 41-2c of the semiconductor device 11c illustrated in FIG. 3, for example. As the depth of the via 41 becomes shallower, the diameter of the via 41 can also be reduced.

The aspect ratio of the via 41 is (depth/width), and even in a case where the aspect ratio is kept constant, the diameter of the via 41 can also be reduced by reducing the depth of the via 41. Since the width (diameter) of the via 41 can be miniaturized, it is also possible to form many external terminal connections (vias 41) in the chip 12j.

The semiconductor device 11j can have a configuration in which the liner film 43 is removed. Therefore, the process of forming the liner film 43 can be reduced, and the number of manufacturing processes can be reduced.

In the configuration of the vias 41 of the semiconductor device 11j illustrated in FIG. 16, similarly to the vias 41 of the semiconductor device 11c illustrated in FIG. 3, the aspect ratios of the vias 41 are the same. Also in the semiconductor device 11j, the width L2j, the width L4j, and the width L6j are set so that the relationship of (depth L1j/width L2j)=(depth L3j/width L4j)=(depth L5j/width L6j) is satisfied.

In the semiconductor device 11j illustrated in FIG. 16, the relationship of the depth L1j of the via 41-1j=the depth L3j of the via 41-2j<the depth L5j of a via 41-3j is satisfied. Therefore, since the aspect ratio related to the via 41-1j, the aspect ratio related to the via 41-2j, and the aspect ratio related to the via 41-3j are adjusted to be substantially the same, the width L2j of the via 41-1 and the width L4j of the via 41-2j are equal, and the width L6j of the via 41-3j is formed to be larger than the width L2j and the width L4j. That is, the widths of the vias 41 are adjusted such that the relationship of width L2j of the via 41-1j=width L4j of the via 41-2j<width L6j of the via 41-3j is satisfied.

As described above, also in the semiconductor device 11j having the configuration in which the chips are stacked, by adjusting the width (diameter) of each via 41 so that the aspect ratios of the vias 41 become substantially the same, the via connected to the lower wiring (wiring layer) having a larger processing amount can have a larger diameter, and the manufacturing becomes easy. The number of manufacturing processes can be reduced by adopting a configuration in which the wiring layer connected to the via 41 is located at a position where the semiconductor substrate does not need to be processed. Therefore, integration of the vias 41, cost reduction, and yield can be improved.

<11th Embodiment>

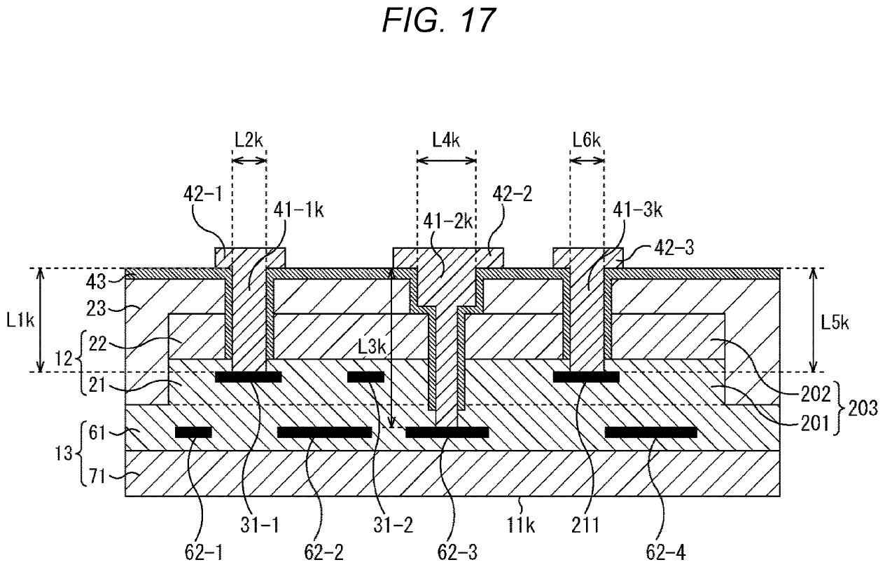

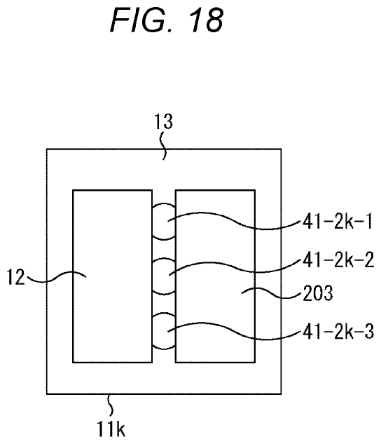

FIG. 17 is a view illustrating a cross-sectional configuration example of a semiconductor device 11k according to an 11th embodiment, and FIG. 18 is a view illustrating a planar configuration example. Portions similar to those of the semiconductor device 11c in the third embodiment illustrated in FIG. 3 are denoted by similar reference numerals, and description thereof is omitted.

The semiconductor device 11k illustrated in FIG. 17 has a configuration in which the chip 12 is stacked on the chip 13 on the left side in the drawing, a chip 203 is formed on the right side in the drawing, and a via 41-2k is formed between the chip 13 and the chip 203.

The chip 13 includes the wiring layer 61 and the semiconductor substrate 71, and wirings 62-1 to 62-4 are formed in the wiring layer 61. The chip 12 includes the wiring layer 21 and the semiconductor substrate 22, and the wiring 31-1 and the wiring 31-2 are formed in the wiring layer 21. The chip 203 includes a wiring layer 201 and a semiconductor substrate 202, and wiring 211 is formed in the wiring layer 201.

By bonding the wiring layer 21 of the chip 12 and the wiring layer 61 of the chip 13, the chip 12 is stacked on the chip 13. By bonding the wiring layer 201 of the chip 203 and the wiring layer 61 of the chip 13, the chip 203 is stacked on the chip 13.

A via 41-1k connected to the wiring 31-1 in the wiring layer 21 of the chip 12 is formed, and the depth of the via 41-1k is a depth L1k and the width is a width L2k. A via 41-3k connected to the wiring 211 in the wiring layer 201 of the chip 203 is formed, and the depth of the via 41-1k is a depth L5k and the width is a width L6k.

An insulating film 23 is formed on a side surface (excluding a side surface on the chip 203 side) and an upper surface of the chip 12. Similarly, an insulating film 23 is formed on a side surface (excluding a side surface on the chip 13 side) and an upper surface of the chip 203.

The via 41-2k is formed between the chip 12 and the chip 203. The via 41-2k is formed with a width (diameter) larger than the interval between the chips in an upper portion of the chip 12 and the chip 203, and is formed with a width (diameter) smaller than the interval between the chips in a lower portion of the chip 12 and the chip 203.

The via 41-2k is connected to the wiring 62-3 in the wiring layer 61 of the chip 13. The depth of the via 41-2k is a depth L3k, which is a distance from the bonding surface between the via 41-2k and the rewiring line 42-2 to the wiring 62-3. The width of the via 41-2k is a width L4k, and corresponds to the opening diameter of the via 41-2k in the bonding surface.

The liner film 43 is formed between the via 41-2k and the chip 12 and between the via 41-2k and the chip 203 to be in an electrically insulated state.

Referring to the plan view of FIG. 18, the chip 12 and the chip 203 are stacked on the chip 13, and vias 41-2k-1 to 41-2k-3 are formed between the chip 12 and the chip 203. A plurality of vias 41-2k can be formed between the chip 12 and the chip 203, and the number of vias may be any number.

Each of the vias 41-2k-1 to 41-2k-3 is formed with a width L2k, and the width L2k is a distance larger than the interval between the chip 12 and the chip 203.

With such a structure, it is possible to highly integrate vias between chips.

In the configuration of the vias 41 of the semiconductor device 11k illustrated in FIG. 17, similarly to the vias 41 of the semiconductor device 11c illustrated in FIG. 3, the aspect ratios of the vias 41 are the same. The aspect ratios including the vias 41 formed between the chips are configured to be the same.

Also in the semiconductor device 11k, the width L2k, the width L4k, and the width L6k are set so that the relationship of (depth L1k/width L2k)=(depth L3k/width L4k)=(depth L5k/width L6k) is satisfied.

In the semiconductor device 11k illustrated in FIG. 17, the relationship of the depth L1k of the via 41-1k=the depth L5k of the via 41-3k<the depth L3k of the via 41-2k is satisfied. Therefore, since the aspect ratio related to the via 41-1k, the aspect ratio related to the via 41-2k, and the aspect ratio related to the via 41-3k are adjusted to be substantially the same, the width L4k of the via 41-2k is formed to be larger than the width L2k of the via 41-1k and the width L6k of the via 41-3k. That is, the widths of the vias 41 are adjusted such that the relationship of the width L2k of the via 41-1k<the width L4k of the via 41-2k and the relationship of the width L6k of the via 41-3k<the width L4k of the via 41-2k are satisfied.

As described above, also in the semiconductor device 11k having a configuration in which a plurality of chips is stacked on one chip, the width (diameter) of each via 41 is adjusted such that the aspect ratios of the vias 41 are substantially the same including the vias 41 formed between the chips, whereby the via connected to the lower wiring (wiring layer) having a larger processing amount can be made larger in diameter, and the manufacturing becomes easier. Therefore, integration of the vias 41, cost reduction, and yield can be improved.

<Manufacture of Semiconductor Device 11k>

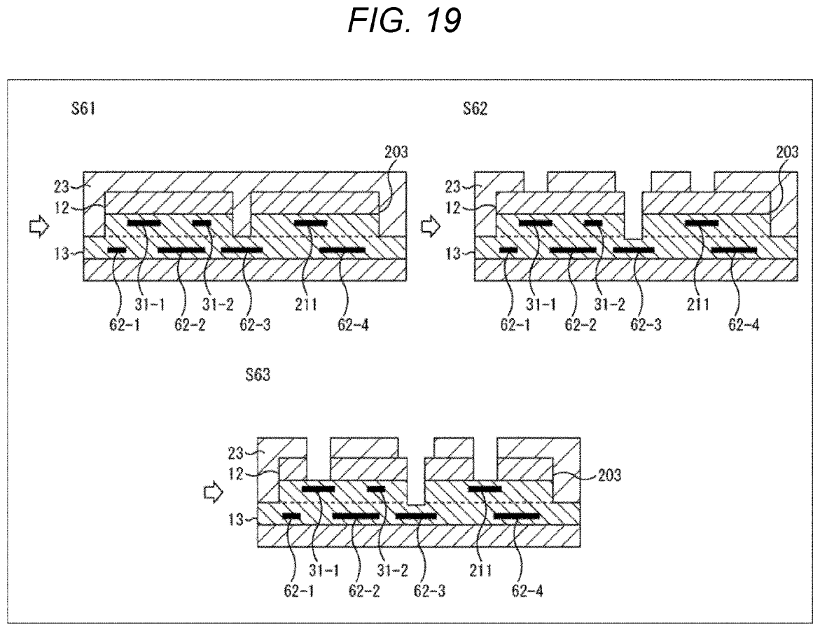

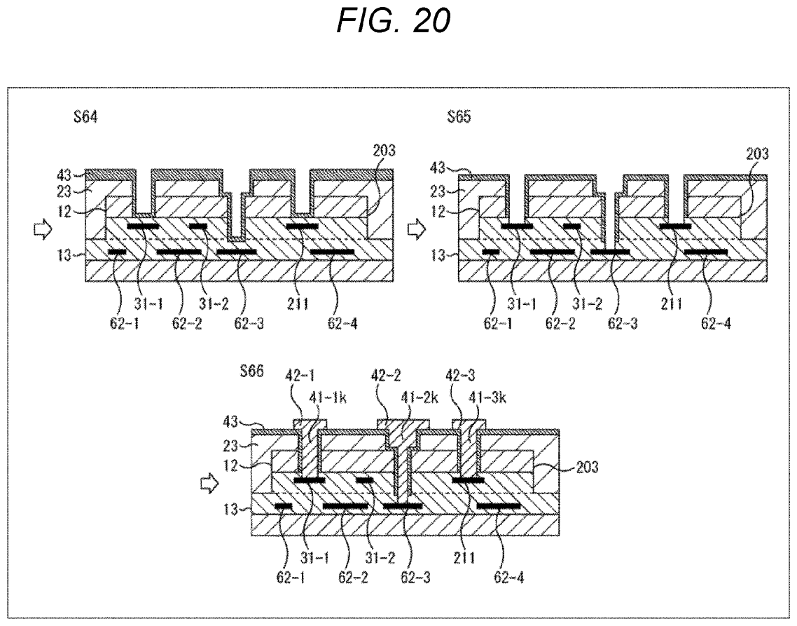

A process relating to the manufacturing of the semiconductor device 11k illustrated in FIG. 17 will be described with reference to FIGS. 19 and 20.

In step S61, the chip 12 and the chip 203 are bonded onto the chip 13, and the chip 12 and the chip 203 are included in the insulating film 23. The interval between the chip 12 and the chip 203 is, for example, about 2 to 10 um.

In step S62, the semiconductor substrate 22 at portions where the via 41-1k and the via 41-3k are formed, the insulating film 23 on the semiconductor substrate 202, and the insulating film 23 between the chip 12 and the chip 203 where the via 41-2k is formed are processed by lithography and dry etching, for example.

The width of the portion where the via 41-1k is formed is larger than the width L2k by the insulating film 23. Similarly, the width of the portion where the via 41-2k is formed is larger than the width L4k by the insulating film 23.

In the dry etching in step S62, the insulating film 23 can be processed at a high selectivity ratio with respect to the semiconductor substrate 22 (203) by using a gas such as C4F8 or C4F6 when the insulating film 23 is SiO2, CHF3 or CH2F2 when the insulating film is SiN, or O2 when the insulating film is an organic resin.

In step S63, the semiconductor substrate 22 and the semiconductor substrate 202 forming the via 41-1k and the via 41-3k are processed by lithography and dry etching, for example.

In step S64 (FIG. 20), the liner film 43, for example, a film constituted by SiO2 is formed by, for example, PE-CVD. The film formation coverage is adjusted so as to be thick at the surface portion and thin at the bottom portion. In one example, the film is formed such that the minimum film thickness of the side surface portions of the semiconductor substrates 22 and 202 is 50 nm or more.

In step S65, the entire surface is processed by dry etching to expose the wiring of each via 41. At this time, the film thickness and coverage of PE-CVD are adjusted so that the liner film 43 of the via 41-2k facing the semiconductor substrate 22 and the semiconductor substrate 202 does not disappear.

In step S66, the via 41-1k, the via 41-2k, and the via 41-3k are formed, and the rewiring line 42-1, the rewiring line 42-2, and the rewiring line 42-3 are formed. The process of step S66 can be performed similarly to step S7 (FIG. 5).

In such a process, the semiconductor device 11k illustrated in FIG. 18 is manufactured. Note that the manufacturing process illustrated here is an example, and is not a description indicating limitation. It is also possible to appropriately change the order of the steps or to perform film formation, processing, or the like by applying a method other than the method described here.

<12th Embodiment>

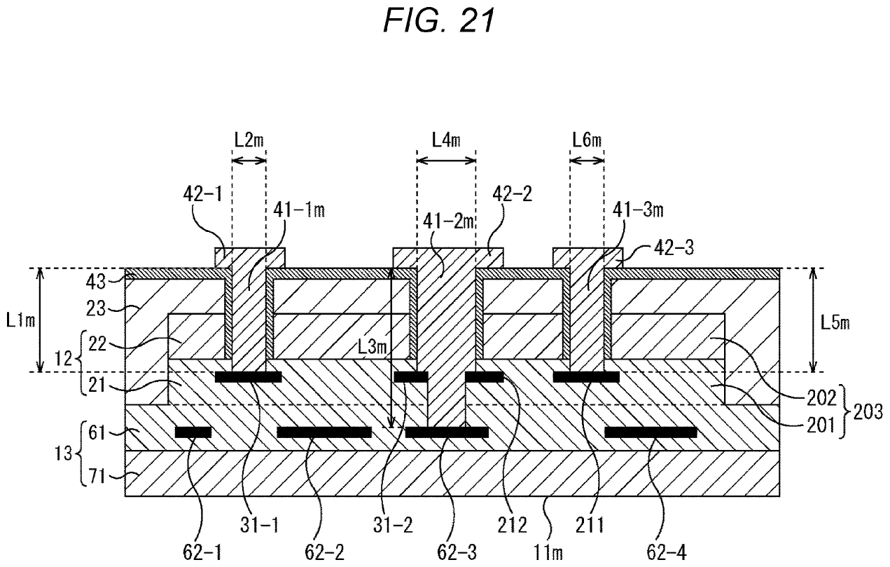

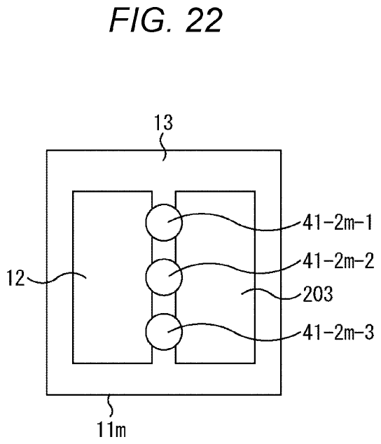

FIG. 21 is a view illustrating a cross-sectional configuration example of a semiconductor device 11m according to a 12th embodiment, and FIG. 22 is a view illustrating a planar configuration example. Similar portions to those of the semiconductor device 11k in the 11th embodiment illustrated in FIGS. 17 and 18 are denoted by similar reference numerals, and description thereof is omitted.

The semiconductor device 11m illustrated in FIG. 21 is different from the semiconductor device 11k illustrated in FIG. 17 in the shape of a via 41-2m provided between the chip 12 and the chip 203, and the other points are similar. The via 41-2m of the semiconductor device 11m illustrated in FIG. 21 is a via connecting the chip 12, the chip 13, and the chip 203.

The wiring 31-2 is provided in the wiring layer 21 of the chip 12, and the wiring 31-2 is connected to the via 41-2m. Wiring 212 is provided in the wiring layer 201 of the chip 203, and the wiring 212 is connected to the via 41-2m. The wiring 62-3 is provided in the wiring layer 61 of the chip 13, and the wiring 62-3 is connected to the via 41-2m.

By providing such a via 41-2m, the signal transmission distance between the chips can be shortened, and the number of vias 41 can be reduced. As illustrated in FIG. 22, a plurality of vias 41-2m can be formed between the chip 12 and the chip 203, and the number of vias may be any number.

Each of vias 41-2m-1 to 41-2m-3 is formed with a width L2m, and the width L2m is substantially the same distance as the interval between the chip 12 and the chip 203.

In the configuration of the vias 41 of the semiconductor device 11m illustrated in FIG. 21, similarly to the vias 41 of the semiconductor device 11c illustrated in FIG. 3, the aspect ratios of the vias 41 are the same. The aspect ratios including the vias 41 formed between the chips are configured to be the same. Also in the semiconductor device 11m, the width L2m, the width L4m, and the width L6m are set so that the relationship of (depth L1m/width L2m)=(depth L3m/width L4m)=(depth L5m/width L6m) is satisfied.

Also in the semiconductor device 11m illustrated in FIG. 21, the relationship of the depth L1m of a via 41-1m=the depth L5m of a via 41-3m<the depth L3m of the via 41-2m is satisfied. Therefore, since the aspect ratio related to the via 41-1m, the aspect ratio related to the via 41-2m, and the aspect ratio related to the via 41-3m are adjusted to be substantially the same, the width L4m of the via 41-2m is formed to be larger than the width L2m of the via 41-1m and the width L6m of the via 41-3m. That is, the widths of the vias 41 are adjusted such that the relationship of the width L2m of the via 41-1m<the width L4m of the via 41-2m and the relationship of the width L6m of the via 41-3m<the width L4m of the via 41-2m are satisfied.

As described above, also in the semiconductor device 11m having a configuration in which a plurality of chips is stacked on one chip, the width (diameter) of each via 41 is adjusted such that the aspect ratios of the vias 41 are substantially the same including the vias 41 formed between the chips, whereby the via connected to the lower wiring (wiring layer) having a larger processing amount can be made larger in diameter, and the manufacturing becomes easier. Therefore, integration of the vias 41, cost reduction, and yield can be improved.

<13th Embodiment>

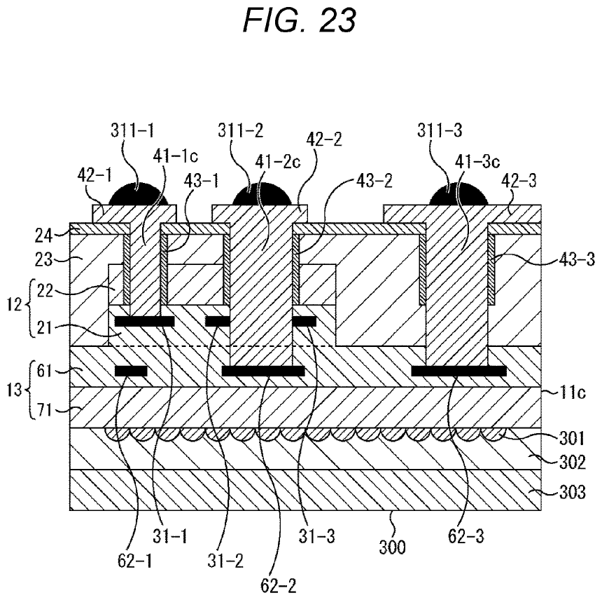

As a 13th embodiment, a case where any of the semiconductor devices 11 of the first to 12th embodiments is applied to an imaging element will be described. FIG. 23 is a diagram illustrating a configuration example in a case where the semiconductor device 11c according to the third embodiment is applied to an imaging element.

The chip 13 included in an imaging element 300 is used as a back-illuminated solid-state imaging element. A photodiode (PD) is formed on the semiconductor substrate 71 of the chip 13, and an on-chip lens 301 is formed on the light incident surface side. Adhesive 302 is disposed on at least a part of the surface of the semiconductor substrate 22 on the side where the on-chip lens 301 is formed, and a transparent substrate 303 is stacked.

The chip 12 is stacked on the chip 13 as the solid-state imaging element. The chip 12 can be a chip on which a processing circuit for processing a signal obtained from a solid-state imaging element and a memory are formed.

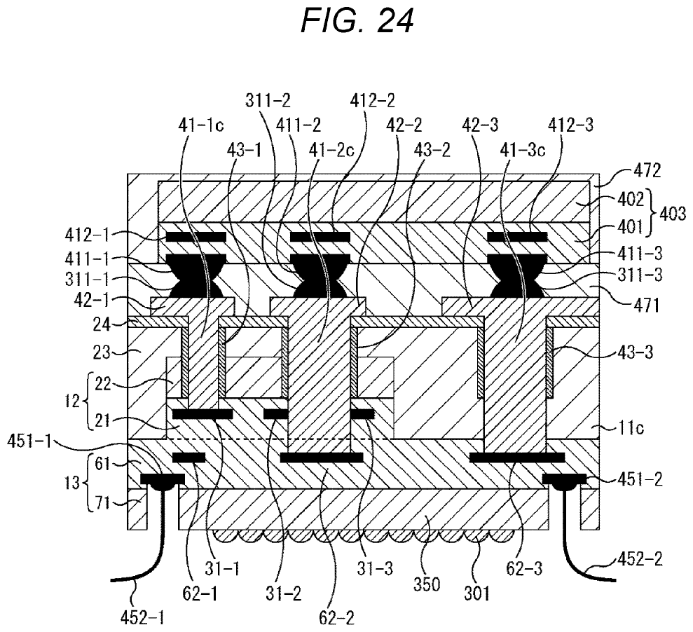

A bump 311-1 is formed on the rewiring line 42-1 bonded to the via 41-1c, a bump 311-2 is formed on the rewiring line 42-2 bonded to the via 41-2c, and a bump 311-3 is formed on the rewiring line 42-3 bonded to the via 41-3c. As described with reference to FIG. 24, the bump 311 is used for connection with another chip when another chip or the like is stacked.

In the imaging element 300, an external connection wiring is formed by the via 41. With such a structure, it is possible to perform a chip size package even in a case where another chip is stacked on the solid-state imaging element, and it is possible to obtain a structure advantageous for miniaturization of the package and high performance of the solid-state imaging element.

<14th Embodiment>

As a 14th embodiment, a configuration in which a chip is further stacked on the imaging element 300 in the 13th embodiment will be described.

An imaging element 350 illustrated in FIG. 24 has a configuration in which a chip 403 is further stacked on the semiconductor device 11c. The chip 403 has a configuration in which a wiring layer 401 and a semiconductor substrate 402 are stacked. In the wiring layer 401, bumps 411-1 to 411-3 and wirings 412-1 to 412-3 are formed.

The bumps 411-1 to 411-3 formed on the chip 403 are bonded to the bumps 311-1 to 311-3 formed on the semiconductor device 11c. A portion where the bumps 411-1 to 411-3 and the bumps 311-1 to 311-3 are bonded is filled with an underfill material 471 and protected.

The side surface and the upper surface of the chip 403 are configured such that a molding material 472 is disposed and protected. The underfill material 471 and the molding material 472 can provide the imaging element 350 with improved mechanical strength.

The imaging element 350 illustrated in FIG. 24 is an example in which an external connection wiring is configured in addition to the via 41. In the imaging element 350 illustrated in FIG. 24, in a chip 13 as a solid-state imaging element, a pad 451-1 and a pad 451-2 connected to external connection wiring such as wire bonding or bumps are formed on the light incident surface side of the semiconductor substrate 71. FIG. 24 illustrates a configuration in which connection to the outside is performed by wire bonding. A wire 452-1 and a wire 452-2 are connected to the pad 451-1 and the pad 451-2.

The configuration of the imaging element 350 illustrated in FIG. 24 is also a configuration capable of further integrating semiconductor elements.

The first to 14th embodiments described above can be implemented in appropriate combination.

<Configuration of Electronic Device>

The imaging element 300 illustrated in FIG. 23 and the imaging element 350 illustrated in FIG. 24 can be applied to various electronic devices such as an imaging device such as a digital still camera or a digital video camera, a mobile phone having an imaging function, or another device having an imaging function, for example.

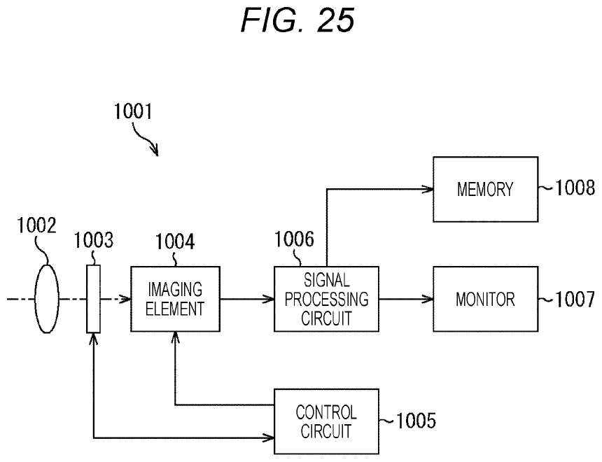

FIG. 25 is a block diagram illustrating a configuration example of an imaging device as an electronic device. An imaging device 1001 illustrated in FIG. 25 includes an optical system 1002, a shutter device 1003, an imaging element 1004, a drive circuit 1005, a signal processing circuit 1006, a monitor 1007, and a memory 1008, and can capture a still image and a moving image.

The optical system 1002 has one or more lenses, and guides light (incident light) from a subject to the imaging element 1004 and forms as an image on a light receiving surface of the imaging element 1004.

The shutter device 1003 is arranged between the optical system 1002 and the imaging element 1004, and controls a light irradiation period and a shading period with respect to the imaging element 1004 in accordance with the control of the drive circuit 1005.

The imaging element 1004 includes a package including the above-described imaging element. The imaging element 1004 accumulates signal charges for a certain period of time in accordance with light formed as an image on the light receiving surface via the optical system 1002 and the shutter device 1003. The signal charges accumulated in the imaging element 1004 are transferred in accordance with a drive signal (a timing signal) supplied from the drive circuit 1005.

The drive circuit 1005 outputs a drive signal for controlling a transfer operation of the imaging element 1004 and a shutter operation of the shutter device 1003, to drive the imaging element 1004 and the shutter device 1003.

The signal processing circuit 1006 performs various kinds of signal processing on the signal charges outputted from the imaging element 1004. The image (image data) obtained by the signal processing applied by the signal processing circuit 1006 is supplied to the monitor 1007 to be displayed or supplied to the memory 1008 to be stored (recorded).

Also in the imaging device 1001 configured as described above, the imaging element 300 or the imaging element 350 including any of the semiconductor devices 11a to k described above can be applied to the optical system 1002 and the imaging element 1004.

### Application Example to Endoscopic Surgery System

The technology according to the present disclosure (present technology) can be applied to various products. For example, the technology according to the present disclosure may be applied to an endoscopic surgery system.

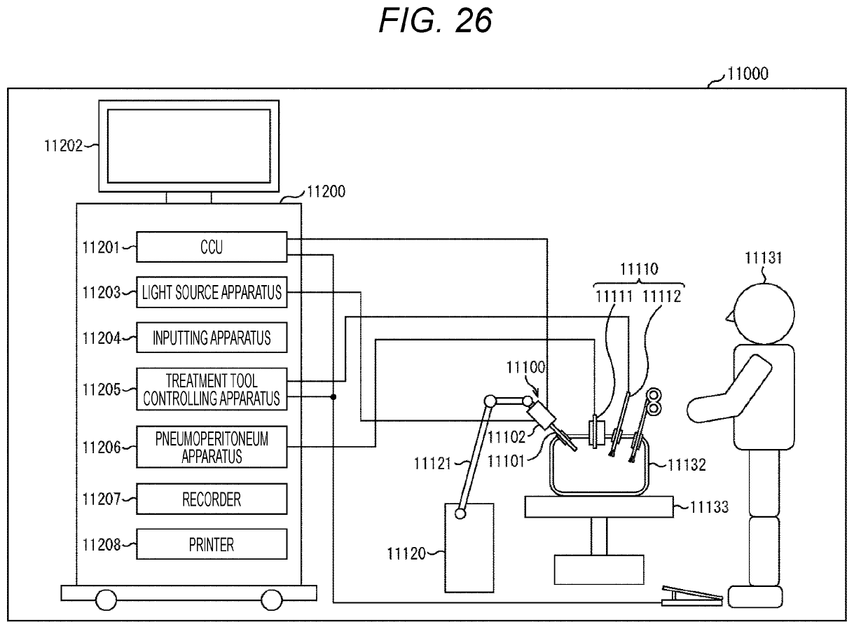

FIG. 26 is a view depicting an example of a schematic configuration of an endoscopic surgery system to which the technology according to an embodiment of the present disclosure (present technology) can be applied.

In FIG. 26, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

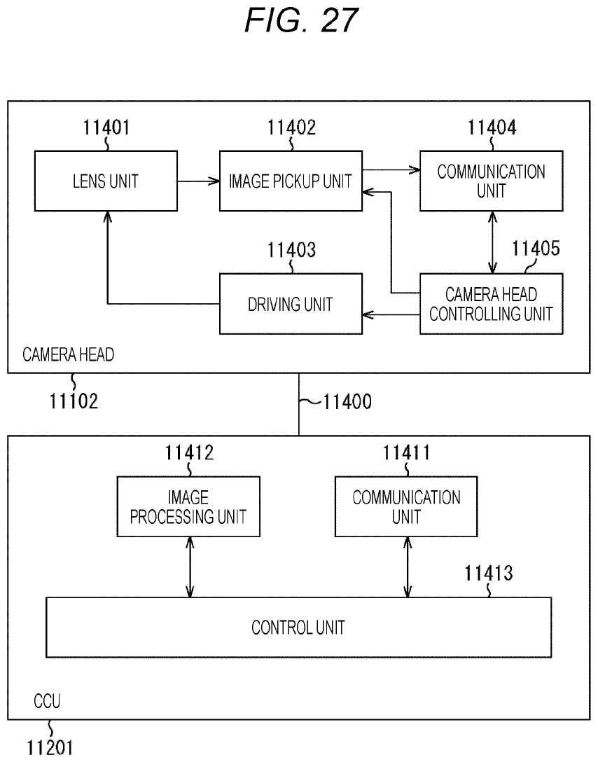

FIG. 27 is a block diagram depicting an example of a functional configuration of the camera head 11102 and the CCU 11201 depicted in FIG. 26.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

### Application Example to Moving Body

The technology according to the present disclosure (present technology) can be applied to various products. For example, the technology according to the present disclosure may be implemented as a device mounted on any type of moving body such as an automobile, an electric vehicle, a hybrid electric automobile, a motorcycle, a bicycle, a personal mobility, an airplane, a drone, a ship, a robot, and the like.

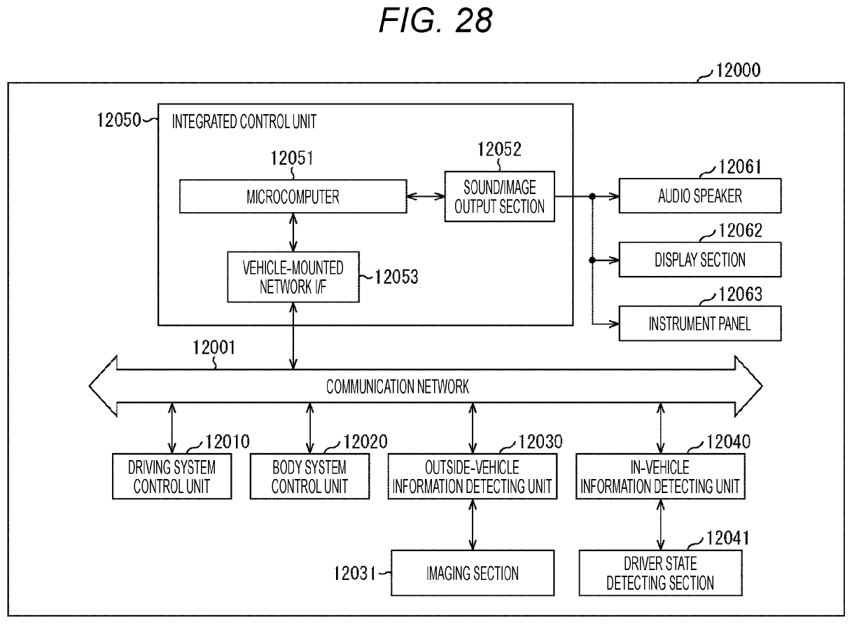

FIG. 28 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 28, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example in FIG. 28, as the output device, an audio speaker 12061, a display section 12062, and an instrument panel 12063 are illustrated. The display section 12062 may, for example, include at least one of an on-board display and a head-up display.

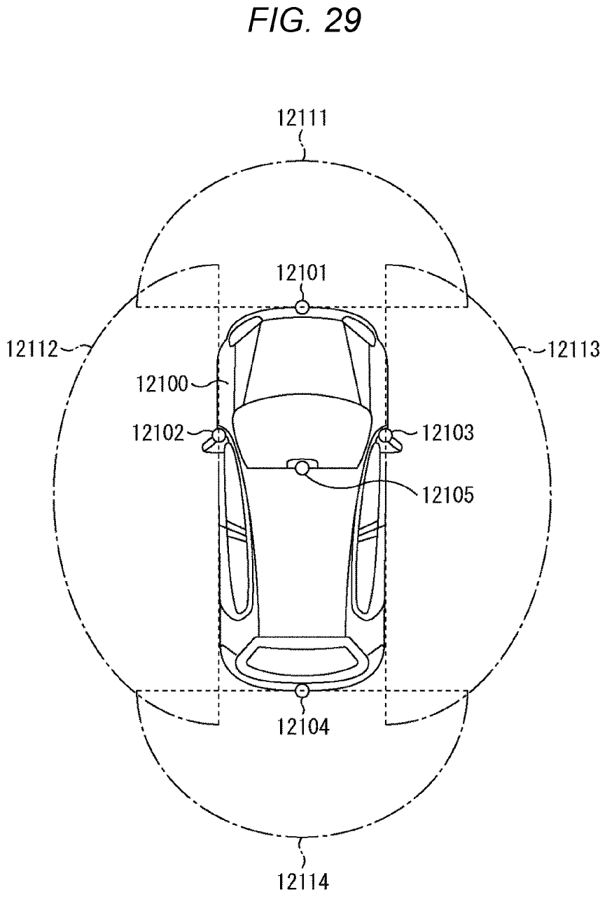

FIG. 29 is a diagram depicting an example of the installation position of the imaging section 12031.

In FIG. 29, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that, in FIG. 29, an example of imaging ranges of the imaging sections 12101 to 12104 is illustrated. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

In the present specification, the system represents the entire apparatus including a plurality of apparatuses.

Note that, the effects described in the present specification are merely examples and are not limited, and there may be other effects.

Note that the embodiments of the present technology are not limited to the above-described embodiments, and various modifications are possible without departing from the scope of the present technology.

Note that the present technology can also have the following configuration.

(1)

A semiconductor device including
a plurality of vias,
in which an aspect ratio defined by a depth and a width of a via is substantially same in the plurality of vias.

(2)

The semiconductor device according to (1),

in which the via is connected to wiring in a wiring layer constituting a chip.

(3)

The semiconductor device according to (1) or (2),

in which the plurality of vias includes a first via penetrating a chip stacked in a wiring layer and a second via not penetrating the chip.

(4)

The semiconductor device according to (3),

in which in a case where the first via and the second via are connected to wiring having a same depth, an aspect ratio of the first via and an aspect ratio of the second via are different from each other.

(5)

The semiconductor device according to any one of (1) to (4),
in which a second chip is stacked on a first chip, and
the plurality of vias includes a first via connected to first wiring in a first wiring layer included in the first chip and a second via connected to second wiring in a second wiring layer included in the second chip.

(6)

The semiconductor device according to (5),

in which a width of the first via changes in the second wiring layer.

(7)

The semiconductor device according to (5),

in which wiring formed on a surface of the first wiring layer and wiring formed on a surface of the second wiring layer are bonded.

(8)

The semiconductor device according to any one of (5) to (7),
in which the second chip and a third chip are stacked on the first chip,
the third chip is a dummy chip, and
the first via penetrates the third chip and is connected to the first wiring.

(9)

The semiconductor device according to (8),

in which the third chip is constituted by a same material as the second chip.

(10)

The semiconductor device according to (8),

in which wiring formed on a surface of a wiring layer of the third chip and wiring formed on a surface of the first wiring layer are bonded.

(11)

The semiconductor device according to any one of (5) to (10),

in which an insulating film of a same material is formed on a side surface and an upper surface of the second chip, a side surface of the first via, and a side surface of the second via.

(12)

The semiconductor device according to any one of (5) to (11),
in which the second chip has a configuration in which a semiconductor substrate having an area smaller than an area of the second wiring layer is stacked on the second wiring layer, and
the second via is formed in a region of the second wiring layer where the semiconductor substrate is not stacked.

(13)

The semiconductor device according to any one of (5) to (12),

in which the first wiring layer of the first chip and the semiconductor substrate of the second chip are bonded.

(14)

The semiconductor device according to any one of (1) to (13),
in which a first chip, and a second chip and a third chip smaller than the first chip are stacked on the first chip, and
the plurality of vias includes vias formed between the second chip and the third chip.

(15)

The semiconductor device according to (14),
in which a width of a portion of the via located above the second chip is larger than a width of an interval between the second chip and the third chip, and
a width of a portion of the via located below the second chip is smaller than a width of an interval between the second chip and the third chip.

(16)

The semiconductor device according to (14),

in which the via is connected to first wiring formed in a wiring layer of the first chip, second wiring formed in a wiring layer of the second chip, and third wiring formed in a wiring layer of the third chip.

(17)

The semiconductor device according to any one of (5) to (16),

in which the first chip is a solid-state imaging element.

(18)

The semiconductor device according to any one of (1) to (17),

in which the aspect ratio is in a range of 1 to 20.

(19)

An imaging device including:
a first chip on which a solid-state imaging element is formed;
a second chip that processes a signal from the first chip; and
a plurality of vias formed in the first chip and the second chip,
in which an aspect ratio defined by a depth and a width of a via is substantially same in the plurality of vias.

(20)

A manufacturing method for manufacturing a semiconductor device including a plurality of vias, the manufacturing method including

forming a hole in which a width of a via is set such that an aspect ratio defined by a depth and a width of the via is substantially same in the plurality of vias.

### REFERENCE SIGNS LIST

11 Semiconductor device
12, 13 Chip
21 Wiring layer
22 Semiconductor substrate
23 Insulating film
24 Stopper film
31 Wiring
41 Via
42 Rewiring line
43 Liner film
61 Wiring layer
62 Wiring
71 Semiconductor substrate
81, 82, 83 Hole
91 Resist mask
101 Wiring
121 Wiring layer
122 Semiconductor substrate
123 Dummy chip
131 Wiring
141 Wiring
151, 152, 153 Hole
201 Wiring layer
202 Semiconductor substrate
203 Chip
211, 212 Wiring
300 Imaging element
301 On-chip lens
302 Adhesive
303 Transparent substrate
311 Bump
350 Imaging element
401 Wiring layer
402 Semiconductor substrate
403 Chip
411 Bump
412 Wiring
451 Pad
452 Wire
471 Underfill material
472 Molding material

1. A semiconductor device comprising
a plurality of vias,
wherein an aspect ratio defined by a depth and a width of a via is substantially same in the plurality of vias.

2. The semiconductor device according to claim 1,
wherein the via is connected to wiring in a wiring layer constituting a chip.

3. The semiconductor device according to claim 1,
wherein the plurality of vias includes a first via penetrating a chip stacked in a wiring layer and a second via not penetrating the chip.

4. The semiconductor device according to claim 3,
wherein in a case where the first via and the second via are connected to wiring having a same depth, an aspect ratio of the first via and an aspect ratio of the second via are different from each other.

5. The semiconductor device according to claim 1,
wherein a second chip is stacked on a first chip, and
the plurality of vias includes a first via connected to first wiring in a first wiring layer included in the first chip and a second via connected to second wiring in a second wiring layer included in the second chip.

6. The semiconductor device according to claim 5,
wherein a width of the first via changes in the second wiring layer.

7. The semiconductor device according to claim 5,
wherein wiring formed on a surface of the first wiring layer and wiring formed on a surface of the second wiring layer are bonded.

8. The semiconductor device according to claim 5,
wherein the second chip and a third chip are stacked on the first chip,
the third chip is a dummy chip, and
the first via penetrates the third chip and is connected to the first wiring.

9. The semiconductor device according to claim 8,
wherein the third chip is constituted by a same material as the second chip.

10. The semiconductor device according to claim 8,
wherein wiring formed on a surface of a wiring layer of the third chip and wiring formed on a surface of the first wiring layer are bonded.

11. The semiconductor device according to claim 5,
wherein an insulating film of a same material is formed on a side surface and an upper surface of the second chip, a side surface of the first via, and a side surface of the second via.

12. The semiconductor device according to claim 5,
wherein the second chip has a configuration in which a semiconductor substrate having an area smaller than an area of the second wiring layer is stacked on the second wiring layer, and
the second via is formed in a region of the second wiring layer where the semiconductor substrate is not stacked.

13. The semiconductor device according to claim 5,
wherein the first wiring layer of the first chip and the semiconductor substrate of the second chip are bonded.

14. The semiconductor device according to claim 1,
wherein a first chip, and a second chip and a third chip smaller than the first chip are stacked on the first chip, and
the plurality of vias includes vias formed between the second chip and the third chip.

15. The semiconductor device according to claim 14,
wherein a width of a portion of the via located above the second chip is larger than a width of an interval between the second chip and the third chip, and
a width of a portion of the via located below the second chip is smaller than a width of an interval between the second chip and the third chip.

16. The semiconductor device according to claim 14,
wherein the via is connected to first wiring formed in a wiring layer of the first chip, second wiring formed in a wiring layer of the second chip, and third wiring formed in a wiring layer of the third chip.

17. The semiconductor device according to claim 5,
wherein the first chip is a solid-state imaging element.

18. The semiconductor device according to claim 1,
wherein the aspect ratio is in a range of 1 to 20.

19. An imaging device comprising:
a first chip on which a solid-state imaging element is formed;
a second chip that processes a signal from the first chip; and
a plurality of vias formed in the first chip and the second chip,
wherein an aspect ratio defined by a depth and a width of a via is substantially same in the plurality of vias.

20. A manufacturing method for manufacturing a semiconductor device including a plurality of vias, the manufacturing method comprising
forming a hole in which a width of a via is set such that an aspect ratio defined by a depth and a width of the via is substantially same in the plurality of vias.
